(19) United States
(12) Patent Application Publication
(10) Pub. No.: US 2026/0334198 A1
(43) Pub. Date: Oct. 22, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Harry-HakLay CHUANG, Zhubei City (TW); Kuo-Chyuan TZENG, Chu-Pei City (TW); Da-Cheng HUANG, Taichung City (TW); Chen-Chin LIU, Hsinchu City (TW); Jui-Tsung LIEN, Hsinchu City (TW)

(21) Appl. No.: 19/183,175

(22) Filed: Apr. 18, 2025

(51) Int. Cl. H01L 23/522; H01L 21/768; H01L 23/528; H01L 23/544; H10B 61/00; H10N 50/10; H10N 50/80

(52) U.S. Cl. CPC H10W 20/42; H10B 61/10; H10N 50/10; H10N 50/80; H10W 20/056; H10W 20/082; H10W 20/435; H10W 20/498; H10W 46/00; H10W 46/301

(57) ABSTRACT

A vertical dimension (e.g., height or depth) of bottom electrode vias for a plurality of memory devices is increased in comparison to vertical dimensions of bottom electrode vias of other memory devices. The resulting bottom electrode via vertical dimension provides sufficient topography for an adjacent alignment mark region so that additional etching and an additional mask to form a remainder of an alignment mark region are not needed. As a result of the increased vertical dimension, the same etching operation may be used to form recesses for bottom electrode vias and to form sufficiently deep alignment mark recesses. Additionally, a metallization structure commonly contacts a top electrode layer on a magnetic tunnel junction structure of each memory device of the plurality of memory devices. Accordingly, masks and etching operations that would be needed to form an intervening top electrode structure can be omitted, and manufacturing processes may be simplified.

### BACKGROUND

A semiconductor device may include a non-volatile memory, which is able to store data in the absence of power. Non-volatile memory technologies include magneto-resistive random-access memory (MRAM), phase change random access memory (PC-RAM), and resistive random access memory (RRAM), among other examples. These non-volatile memory technologies are compatible with complementary metal-oxide-semiconductor (CMOS) logic fabrication processes, which enables logic and memory circuitry to be integrated onto the same semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example semiconductor device including an example semiconductor memory structure described herein.

FIGS. 2A-2G are diagrams of an example implementation of forming a semiconductor device described herein.

FIGS. 3A-3O are diagrams of an example implementation of forming a portion of a semiconductor device described herein.

FIGS. 4A and 4B are diagrams of an example implementation of forming a portion of a semiconductor device described herein.

FIG. 5 is a flowchart of an example process associated with forming a semiconductor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An MRAM cell may include a memory device having a magnetic tunnel junction (MTJ) structure arranged vertically between a bottom electrode and a top electrode. Multiple memory devices may be connected to a metallization structure through a single via connected to a top electrode structure that is used for the multiple memory devices. In addition, bottom electrodes are connected to metallization structures through bottom electrode vias. Due to the vertical dimension (e.g., height or depth) of the bottom electrode vias, processing to manufacture the multiple memory devices may require multiple mask layers. In more detail, the vertical dimension of a bottom electrode via may not provide sufficient topography for an adjacent alignment mark region. As a result, in addition to mask(s) used to form recesses for the bottom electrode vias, another mask covering the bottom electrode vias and/or the bottom electrode via recesses needs to be added when performing additional etching to increase the vertical dimension of the adjacent alignment mark region. In addition, the process to form a top electrode structure that is to be used for multiple memory devices requires multiple masks.

In some implementations described herein, a vertical dimension (e.g., height or depth) of bottom electrode vias for a plurality of memory devices is increased in comparison to vertical dimensions of bottom electrode vias of other memory devices. The resulting bottom electrode via vertical dimension provides sufficient topography for an adjacent alignment mark region so that additional etching and an additional mask to form a remainder of an alignment mark region are not needed. In more detail, as a result of the increased vertical dimension, the same etching operation may be used to form recesses for bottom electrode vias and to form alignment mark recesses having a sufficient depth. The depth of the bottom electrode via recesses provides for a desired alignment mark recess depth without having to perform an additional etch operation with another etch mask to form a remainder of an alignment mark recess. In addition, a metallization structure of a metallization layer contacts a top electrode layer located on the MTJ structure of each memory device of the plurality of memory devices. As a result, an intervening common top electrode structure is not required to connect a top metallization layer to the memory devices. Accordingly, masks and etching operations that would be needed to form the top electrode structure can be omitted, and manufacturing processes may be simplified.

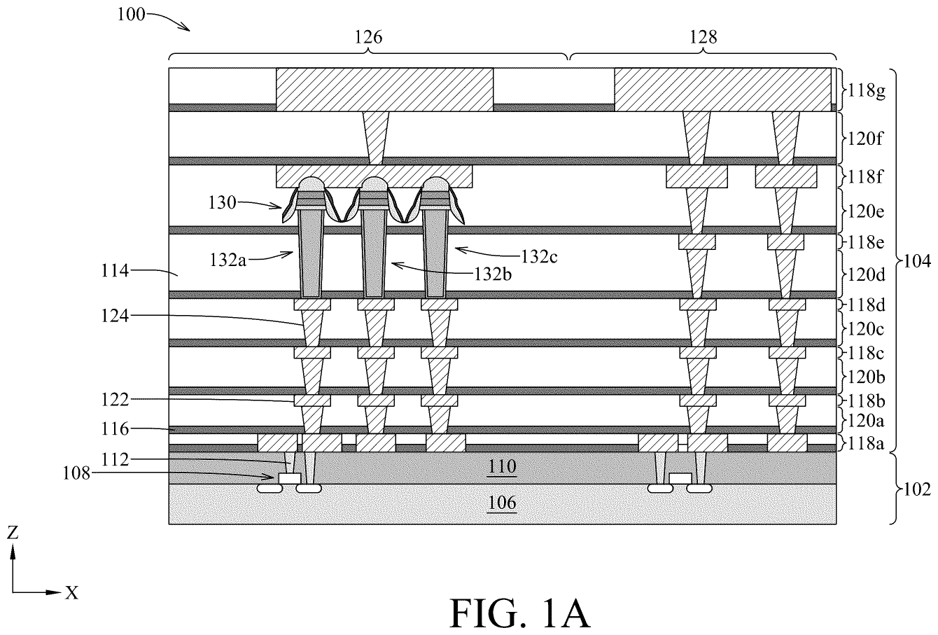

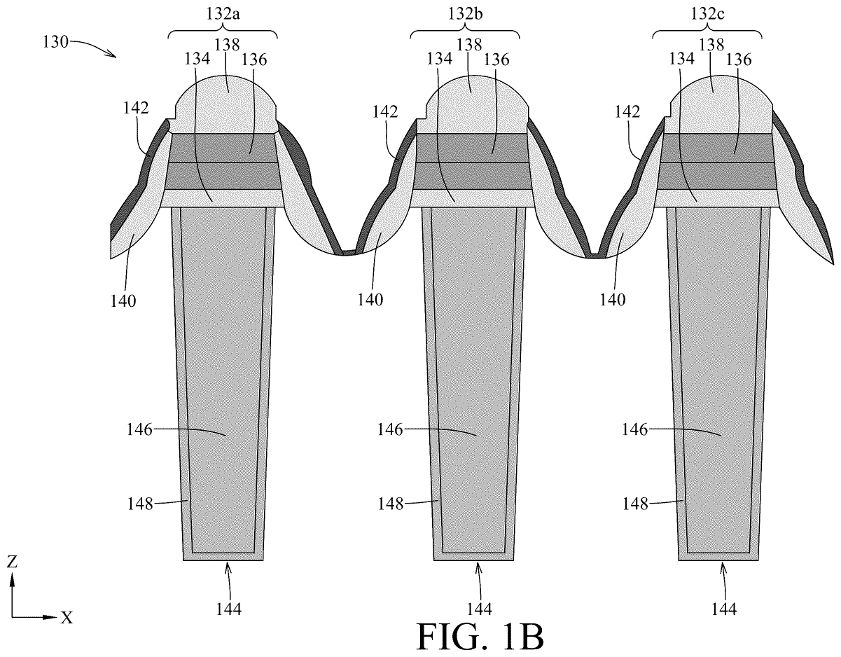

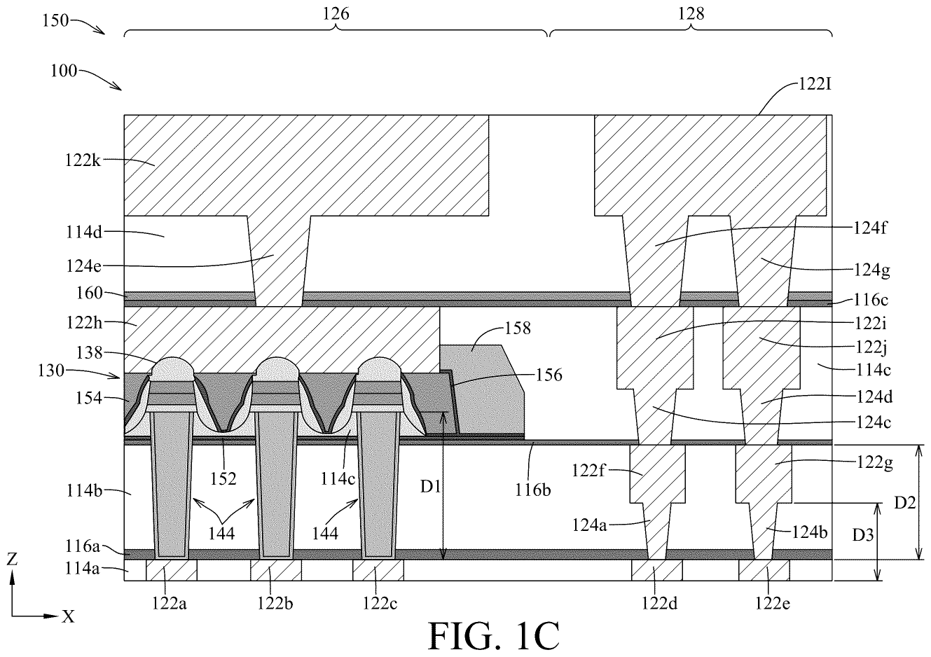

FIGS. 1A-1C are diagrams of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device.

FIG. 1A illustrates a cross-section view of the semiconductor device 100. As shown in FIG. 1A, the semiconductor device 100 may include a device layer 102 and an interconnect layer 104 arranged in a z-direction in the semiconductor device 100 with respect to the device layer 102. For example, the interconnect layer 104 may be located above the device layer 102. As another example, the interconnect layer 104 may be located below the device layer 102.

The interconnect layer 104 may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate 106 of the semiconductor device 100. The substrate 106 may correspond to a portion of a semiconductor wafer on which the semiconductor device 100 is formed. The substrate 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate 106 may extend in an x-direction and/or in a y-direction in the semiconductor device 100 such that the top and bottom surfaces of the substrate 106 are approximately orthogonal to the z-direction in the semiconductor device 100.

Integrated circuit devices 108 may be included in and/or on the substrate 106 in the device layer 102 of the semiconductor device 100. The integrated circuit devices 108 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices.

A front end transistor structure may include a plurality of source/drain regions, which may correspond to doped regions of the substrate 106, separated by a channel region in the substrate 106. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in the y-direction in the semiconductor device 100. Contacts 112 (e.g., source/drain contacts, gate contacts) may extend through the dielectric layer 110 and between the integrated circuit devices 108 and the interconnect layer 104. The contacts may electrically connect the integrated circuit devices 108 to the interconnect layer 104. The contacts 112 may include vias, plugs, and/or another type of elongated electrically conductive structures. The contacts 112 may include tungsten (W), cobalt (Co), ruthenium (Ru), titanium (Ti), aluminum (Al), and/or gold (Au), among other electrically conductive materials.

The interconnect layer 104 includes a plurality of dielectric layers (e.g., back end dielectric layers) that are arranged in a direction (e.g., the z-direction) that is approximately perpendicular to the top surface of the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include a low dielectric constant (low-k) oxide material such as silicon oxide (SiOₓ) or undoped silicate glass (USG). Additionally and/or alternatively, the ILD layers 114 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104. For example, the ILD layers 114 may each include a low-k dielectric material such as USG, and the ESLs 116 may each include a high-k dielectric material such as silicon nitride (SiₓN_{y}) or silicon carbide (SiC), such that a dielectric constant of one or more ESLs 116 is greater than a dielectric constant of one or more ILD layers 114. Additionally and/or alternatively, two or more ESLs 116 may include different materials. For example, one or more first ESLs 116 may include silicon nitride (SiₓN_{y}), and one or more second ESLs 116 may include silicon carbide (SiC).

The interconnect layer 104 includes a plurality of conductive structures that are arranged in a plurality of layers. The conductive structures may be electrically coupled and/or physically coupled with one or more of the integrated circuit devices 108 in the device layer 102. The conductive structures provide electrical routing that enables signals and/or power to be provided to and/or from the integrated circuit devices 108.

The layers of conductive structures may include a plurality of layers 118a-118g that are vertically arranged and alternate with a plurality of layers 120a-120f in the z-direction (e.g., vertically alternate). The layers 118a-118g each include a layer of metallization structures 122 (e.g., metal lines), and the layers 120a-120f each include a layer of interconnect structures 124 (e.g., vias).

The layers 118a-118g of metallization structures 122 may be referred to as M-layers. For example, a layer 118a of metallization structures 122 (referred to as a metal-0 (M0) layer) may be located at the bottom of the interconnect layer 104 and may be coupled with the device layer 102. In particular, the metallization structures 122 in the M0 layer may be coupled with the contacts 112 (e.g., a contact layer referred to as “CO”-layer) of the integrated circuit devices 108 in the device layer 102. A layer 118b of metallization structures 122 (referred to as a metal-1 layer (M1) layer) may be located above the layer 118a of metallization structures 122 in the interconnect layer 104, a layer 118c of metallization structures 122 (referred to as a metal-2 layer (M2) layer) may be located above the layer 118b of metallization structures 122, and so on.

A layer 120a of interconnect structures 124 (referred to as a via-1 (V0) layer) may be included between the M0 layer and the M1 layer to interconnect the M0 layer and the M1 layer, a layer 120b of interconnect structures 124 (referred to as a via-2 (V1) layer) may be included between the M1 layer and the M2 layer to interconnect the M1 layer and the M2 layer, and so on.

The metallization structures 122 may include a combination of trenches, metallization layers, conductive traces, and/or other types of conductive structures. The interconnect structures 124 may include a combination of vias, interconnects, and/or other types of conductive structures. The metallization structures 122 and the interconnect structures 124 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 104 and the metallization structures 122, and/or between the dielectric layers of the interconnect layer 104 the interconnect structures 124. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 122, a topmost layer of interconnect structures 124) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 122, a topmost layer of interconnect structures 124) may be coupled to bonding structures, such as bonding pads and/or bonding vias.

As further shown in FIG. 1A, the semiconductor device may be divided into a memory region 126 and a logic region 128. The memory region 126 may include memory devices and corresponding circuitry. The memory devices may include MRAM devices, PC-RAM devices, and/or RRAM devices, among other examples of devices used for memory storage. The logic region 128 may include logic devices and corresponding circuitry to process data and perform computations. The logic devices may include transistors arranged to perform designated algorithms. A semiconductor structure 130 including a plurality of memory devices 132a, 132b, and 132c is included in the interconnect layer 104 of the semiconductor device 100. The semiconductor structure 130 may extend through and/or is included in one or more dielectric layers in the interconnect layer 104, such as one or more ILD layers 114 and/or one or more ESLs 116. In some implementations, an integrated circuit device 108 is electrically coupled to one or more of the memory devices 132a-132c to form a memory cell (e.g., an MRAM cell or another type of resistance-based memory cell) in the semiconductor device 100. In some implementations, a memory devices 132a, 132b, and/or 132c is a non-volatile memory device configured to store data in the absence of power. In some implementations, a memory device 132a, 132b, and/or 132c is configured to perform another function in the semiconductor device 100.

FIG. 1B is a diagram of the semiconductor structure 130. As shown in FIG. 1B, each memory device 132a-132c includes a stacked structure with a bottom electrode layer 134, an MTJ structure 136 on the bottom electrode layer 134, and a top electrode layer 138 on the MTJ structure 136. The MTJ structure 136 may include a fixed layer and a free layer (e.g., ferromagnetic layers), separated by a tunnel barrier layer, that selectively allow quantum tunneling of electrons. The free and fixed layers may include ferrous materials including a combination of iron (Fe) and one or more of cobalt (Co), boron (B), and/or nickel (Ni), among other examples, and the tunnel barrier layer may include a crystalline material, such as magnesium oxide (MgO) and/or another suitable material. In operation, a magnetic direction associated with the free layer may be aligned in parallel with a magnetic direction associated with the fixed layer to place the MTJ structure 136 into an ON or 1 state, in which quantum tunneling is allowed, and the MTJ structure 136 exhibits a lower resistance. On other hand, the magnetic direction associated with the free layer may be reversed (that is, anti-parallel) relative to the magnetic direction associated with the fixed layer, to place the MTJ structure 136 into an OFF or 0 state, in which quantum tunneling is disallowed, and the MTJ structure 136 exhibits a higher resistance. Although described in connection with an MTJ structure 136, the implementations described herein may also apply to other similarly arranged data-storing portions and/or switching elements that may be used for MRAM devices, RRAM devices, PC-RAM devices, ferroelectric random access memory (FRAM) devices, and/or other types of memory devices.

The bottom electrode layer 134 is a bottom electrode of each memory device 132a-132c, and the top electrode layer 138 is a top electrode of each memory device 132a-132c. The bottom electrode layer 134 and the top electrode layer 138 may include one or more electrically conductive materials. Examples include metals such as molybdenum (Mo), nickel (Ni), iridium (Ir), and chromium (Cr), as well as metal nitrides such as titanium nitride (TiN) or tantalum nitride (TaN), among other examples.

First spacer layers 140 are disposed on and along side surfaces of the bottom electrode layer 134, the MTJ structure 136, and a lower portion of the top electrode layer 138 for each of the memory devices 132a-132c. As shown in FIG. 1B, the first spacer layers 140 may extend below a bottom edge of the bottom electrode layer 134. The first spacer layers 140 may be in direct physical contact with side surfaces of the bottom electrode layer 134, the MTJ structure 136, and the lower portion of the top electrode layer 138. The first spacer layers 140 may include a dielectric material such as a nitride (e.g., a silicon nitride (SiₓN_{y}) and/or another nitride material), and/or another suitable material. The first spacer layers 140 may protect the MTJ structure 136 from moisture.

Second spacer layers 142 are disposed on side surfaces of the first spacer layers 140, and on side surfaces of the lower portion of top electrode layer 138. As shown in FIG. 1B, the second spacer layers 142 may extend below a bottom edge of the bottom electrode layer 134 and/or below bottom edges of the first spacer layers 140. The second spacer layers 142 may be in direct physical contact with the side surfaces of the first spacer layers 140, and the side surfaces of the lower portion of the top electrode layer 138. The second spacer layers 142 may include a dielectric material such as an oxide (e.g., a silicon oxide (SiOₓ), an aluminum oxide (AlₓO_{y}), and/or another oxide material), and/or another suitable material. The second spacer layers 142 may protect the MTJ structure 136 and other layers under the second spacer layers 142 from chemical damage.

The memory devices 132a-132c may be electrically coupled and/or physically coupled to a bottom interconnect structure 144 (e.g., via). The bottom interconnect structures 144 may each include one or more conductive structures in the interconnect layer 104, where the conductive structures include a fill layer 146 and a liner layer 148. The fill layers 146 may include tungsten (W), cobalt (Co), ruthenium (Ru), titanium (Ti), aluminum (Al), copper (Cu), gold (Au), and/or a combination thereof, among other examples of electrically conductive materials. The liner layers 148, which are included on side and bottom surfaces of the bottom interconnect structures 144, are disposed between the dielectric layers of the interconnect layer 104 and the fill layers 146, and/or between a metallization structure 122 under a bottom interconnect structure 144 and the fill layer 146. The liner layers 148 may include barrier liners, adhesion liners, and/or another type of liners. Examples of materials for the liner layers 148 include tantalum nitride (TaN) and/or titanium nitride (TiN), among other examples. The bottom interconnect structures 144 may each be formed in and/or through one or more of the ILD layers 114 and/or ESLs 116.

In some implementations, each of the bottom interconnect structures 144 is disposed under a bottom electrode layer 134 in the z-direction, and is in direct physical contact with a bottom surface of the bottom electrode layer 134. In some implementations, an aspect ratio (e.g., ratio of vertical (z-direction) dimension to horizontal (x-direction) dimension) of each of the bottom interconnect structures 144 is greater than or equal to approximately 5. As noted herein, a vertical dimension (e.g., height or depth) of bottom electrode vias (e.g., bottom interconnect structures 144) for memory devices is increased in comparison to vertical dimensions of bottom electrode vias of other memory devices. As a result of the increased vertical dimension, the same etching operation may be used to form recesses for the bottom electrode vias and to form alignment mark recesses having a sufficient depth. The depth of the bottom electrode via recesses provides for a desired alignment mark recess depth without having to perform additional etching and use additional etch masks to form a remainder of an alignment mark recess. If the aspect ratio of each of the bottom interconnect structures 144 is smaller than 5, then the geometry of the bottom interconnect structures 144 will not provide sufficient topography for an adjacent alignment mark region, so that additional etching and another mask will be needed to form a remainder of a recess in an alignment mark region. In addition, an aspect ratio of each of the bottom interconnect structures 144 that is smaller than 5 may result in wider vias (e.g., greater x-direction dimension), which consumes more chip area. However, other aspect ratio values and ranges are within the scope of this disclosure.

FIG. 1C is a diagram of an example implementation 150 of a portion of the semiconductor device 100 including the semiconductor structure 130. As shown in FIG. 1C, the semiconductor device is divided into a memory region 126 and a logic region 128. The semiconductor device 100 includes ILD layers 114a, 114b, 114c, and 114d, and ESLs 116a, 116b, and 116c. The semiconductor device 100 further includes metallization structures 122a, 122b, 122c, 122d, and 122e in ILD layer 114a, metallization structures 122f and 122g in ILD layer 114b, metallization structures 122h, 122i, and 122j in ILD layer 114c, and metallization structures 122k and 122l in ILD layer 114d. Metallization structures in the same ILD layer may be in the same metallization layer (e.g., one of layers 118a-g), and may have top surfaces that are coplanar with each other.

An interconnect structure 124a is disposed between and connects metallization structures 122d and 122f. An interconnect structure 124b is disposed between and connects metallization structures 122e and 122g. The interconnect structures 124a and 124b are disposed through part of ILD layer 114a and through ESL 116a. An interconnect structure 124c is disposed between and connects metallization structures 122f and 122i. An interconnect structure 124d is disposed between and connects metallization structures 122g and 122j. The interconnect structures 124c and 124d are disposed through part of ILD layer 114b and through ESL 116b. An interconnect structure 124e is disposed between and connects metallization structures 122h and 122k. An interconnect structure 124f is disposed between and connects metallization structures 122i and 122l. An interconnect structure 124g is disposed between and connects metallization structures 122j and 122l. The interconnect structures 124e, 124f, and 124g are disposed through part of ILD layer 114c and through ESL 116c.

The bottom interconnect structures 144 of the semiconductor structure 130 respectively land on the metallization structures 122a, 122b, and 122c to connect respective bottom electrode layers 134 to the respective metallization structures 122a, 122b, and 122c. Each bottom interconnect structure 144 is formed in a portion of the ILD layer 114c, through a bottom surface of the ILD layer 114c, through the ESL 116c, through the ILD layer 114b (e.g., through top and bottom surfaces of the ILD layer 114b), and through the ESL 116a to land on a metallization structure 122a, 122b, or 122c. A vertical dimension D1 (e.g., z-direction dimension) (e.g., height or depth) of each bottom interconnect structure 144 is greater than a combined (e.g., total) vertical dimension D2 (e.g., z-direction dimension) of the interconnect structure 124a and the metallization structure 122f (or of the interconnect structure 124b and the metallization structure 122g). The vertical dimension D1 of each bottom interconnect structure 144 is greater than a combined (e.g., total) vertical dimension D3 (e.g., z-direction dimension) of the interconnect structure 124b and the metallization structure 122e (or of the interconnect structure 124a and the metallization structure 122d).

In some implementations, the vertical dimension D1 may be included in the range of approximately 1100 angstroms to approximately 1400 angstroms. As noted herein, a vertical dimension (e.g., height or depth) of bottom electrode vias (e.g., bottom interconnect structures 144) for memory devices is increased in comparison to vertical dimensions of bottom electrode vias of other memory devices. As a result of the increased vertical dimension, the same etching operation may be used to form recesses for the bottom electrode vias and to form alignment mark recesses having a sufficient depth. The depth of the bottom electrode via recesses provides for a desired alignment mark recess depth without having to perform additional etching and use additional etch masks to form a remainder of an alignment mark recess. If the vertical dimension D1 of each of the bottom interconnect structures 144 is smaller than 1100 angstroms, then the vertical dimension D1 of the bottom interconnect structures 144 will not provide sufficient topography for an adjacent alignment mark region, so that additional etching and another mask will be needed to form a remainder of a recess in an alignment mark region. If the vertical dimension D1 is greater than 1400 angstroms, taller/deeper bottom interconnect structures 144 (e.g., greater z-direction dimension) may consume more chip area. In addition, bottom interconnect structures 144 which are too tall/deep may have electrical conductivity issues and/or exhibit increased resistance. However, other values and ranges are within the scope of this disclosure.

As shown in FIG. 1C, a majority portion of each bottom interconnect structure 144 is disposed in the ILD layer 114b, and a remaining portion is disposed in the ILD layer 114c. For example, “majority portion” may refer to more than half of the vertical dimension D1. In some implementations, more than 75% of the vertical dimension D1 is disposed in the ILD layer 114b, and a remaining portion of the vertical dimension D1 is disposed in the ILD layer 114c. Additionally, “majority portion” may refer to a majority (e.g., more than half) of the area and/or volume of a bottom interconnect structure 144 being disposed in the ILD layer 114b, with a remaining portion being disposed in the ILD layer 114c.

The metallization structure 122h is commonly connected to the top electrode layer 138 of each memory device 132a, 132b, and 132c. The metallization structure 122h is in direct contact with a surface of the top electrode layer 138 of each memory device 132a, 132b, and 132c. In some implementations, the surface of the top electrode layer 138 of each memory device 132a, 132b, and 132c with which the metallization structure 122h is in direct contact is curved. The semiconductor structure 130 includes three memory devices 132a, 132b, and 132c. Alternatively, the semiconductor structure 130 may include more or fewer than three memory devices.

In the example implementation 150, an oxide layer 152 (e.g., an aluminum oxide (AlₓO_{y}) layer) may be disposed on the ESL 116b in the memory region 126, such that the bottom interconnect structures 144 may also be disposed through the oxide layer 152. An atomic layer deposition (ALD) oxide layer 154 may be disposed around the memory devices 132a-132c on the second spacer layers 142. Some examples of ALD oxides include a zinc oxide (e.g., ZnO), an aluminum oxide (e.g., AlₓO_{y}), an aluminum-zinc oxide (e.g., Al—ZnO), a titanium oxide (e.g., TiOₓ), among other examples. A layer 156 disposed on the ALD oxide layer 154 may include the same or a similar material to that of the second spacer layers 142. A plasma-enhanced ALD (PEALD) oxide layer 158 is disposed on the layer 156 and over the oxide layer 152 and a portion of the ESL 116b in the memory region 126. The PEALD oxide layer 158 may include a zinc oxide (e.g., ZnO), an aluminum oxide (e.g., AlₓO_{y}), an aluminum-zinc oxide (e.g., Al—ZnO), a titanium oxide (e.g., TiOₓ), among other examples. A dielectric layer 160 may be disposed on the ESL 116c. In some implementations, the dielectric layer 160 includes USG.

As indicated above, FIGS. 1A-1C are provided as examples. Other examples may differ from what is described with regard to FIGS. 1A-1C.

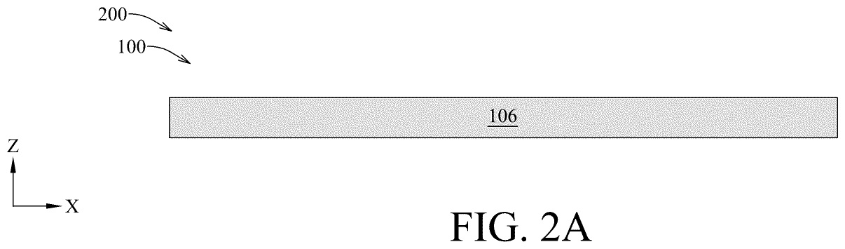

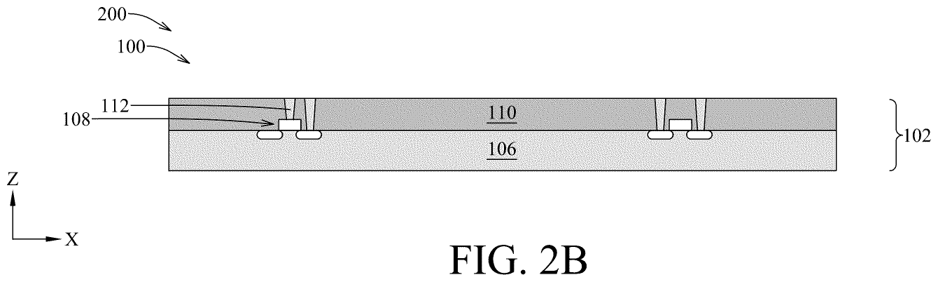

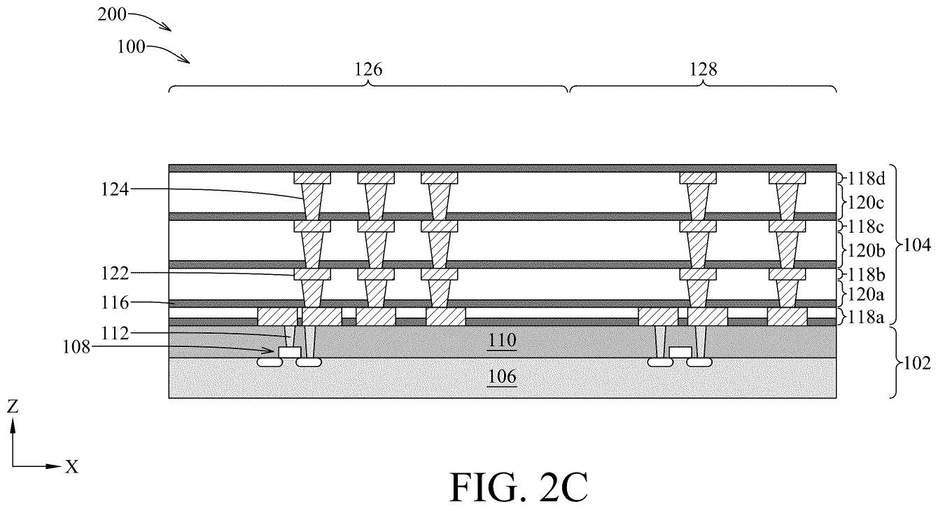

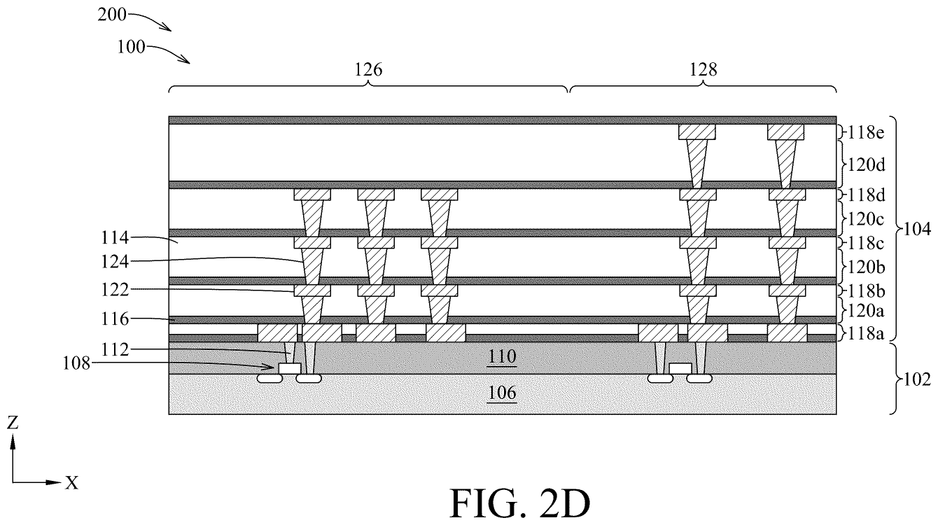

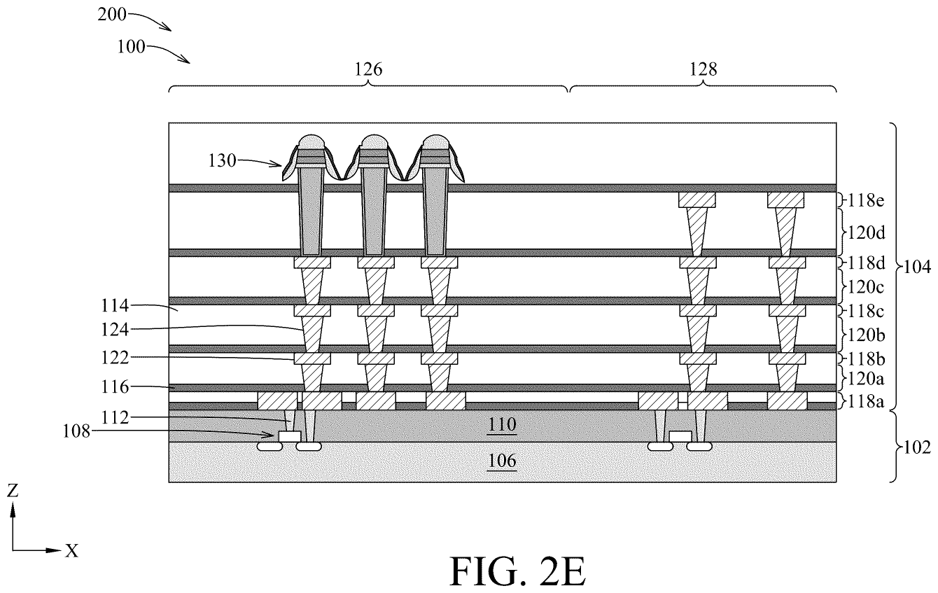

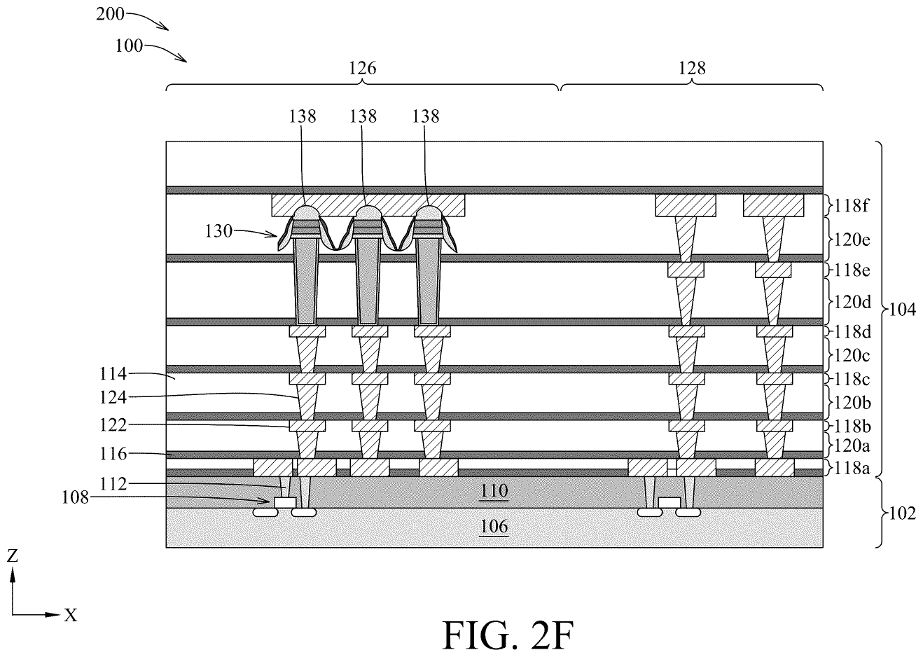

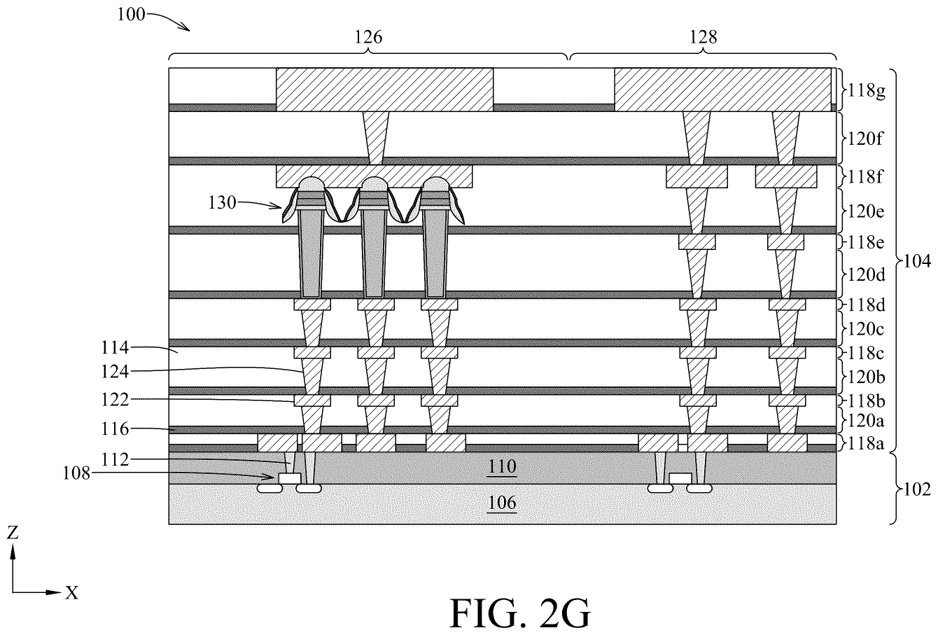

FIGS. 2A-2G are diagrams of an example implementation 200 of forming the semiconductor device 100 described herein. In some implementations, one or more of the semiconductor processing operations described in connection with FIGS. 2A-2G may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 2A, the substrate 106 is provided. The substrate 106 may be provided in the form of a semiconductor wafer such as a silicon (Si) wafer, an SOI wafer, and/or another type of semiconductor work piece. The semiconductor device 100 may be formed on the semiconductor wafer with other semiconductor devices.

As shown in FIG. 2B, the integrated circuit devices 108 may be formed in and/or on the substrate 106 in the device layer 102 of the semiconductor device 100. One or more semiconductor processing tools may be used to form one or more portions of the integrated circuit devices 108. For example, an ion implantation tool may be used to dope one or more regions in the substrate 106 with one or more types of dopants to form well regions, implant regions, and/or other types of doped regions in the substrate 106 for the integrated circuit devices 108. As another example, a deposition tool may be used to perform various deposition operations to deposit layers and/or structures of the integrated circuit devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the integrated circuit devices 108. As another example, a planarization tool may be used to planarize portions of the integrated circuit devices 108. As another example, a plating tool may be used to deposit metal structures and/or layers of the integrated circuit devices 108.

As further shown in FIG. 2B, a deposition tool is used to deposit the dielectric layer 110 over and/or on the substrate 106 and over and/or on the integrated circuit devices 108. A deposition tool may be used to deposit the dielectric layer 110 using a physical vapor deposition (PVD) technique, an ALD technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 110 after the dielectric layer 110 is deposited.

As further shown in FIG. 2B, the contacts 112 of the integrated circuit devices 108 may be formed through the dielectric layer 110. The contacts 112 may be formed in recesses in the dielectric layer 110. In some implementations, a pattern in a photoresist layer is used to etch the dielectric layer 110 to form the recesses. In these implementations, a deposition tool may be used to form the photoresist layer on the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 110 based on a pattern to form the recesses.

The contacts 112 may be formed in the recesses. In some implementations, a contact 112 (e.g., a gate contact) is formed on a gate structure of an integrated circuit device 108. In some implementations, a contact 112 (e.g., a source/drain contact) is formed on a source/drain region of an integrated circuit device 108. A deposition tool may be used to deposit the material of the contacts 112 in the recesses using a CVD technique, a PVD technique, an ALD technique, an electroplating technique, and/or another suitable deposition technique. The material of the contacts 112 may be deposited in one or more deposition operations. In some implementations, a seed layer is first deposited, and the material of the contacts 112 is deposited on the seed layer. In some implementations, a planarization tool is used to perform a planarization operation (e.g., a CMP operation) to planarize the contacts 112 after the contacts 112 are deposited such that the tops of the contacts 112 are approximately co-planar with the top of the dielectric layer 110.

As shown in FIG. 2C, a first portion of the interconnect layer 104 of the semiconductor device 100 is formed above the dielectric layer 110. One or more deposition tools are used to deposit alternating layers of ILD layers 114 and ESLs 116 in the first portion of the interconnect layer 104 of the semiconductor device 100. In this way, the ILD layers 114 and ESLs 116 may be arranged in the z-direction in the semiconductor device 100. One or more deposition tools may be used to deposit each of the ILD layers 114 and each of the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As further shown in FIG. 2C, a deposition tool, an exposure tool, a developer tool, an etch tool, a planarization tool, a plating tool, and/or another semiconductor processing tool may be used to perform various operations to form the metallization structures 122 and to form the interconnect structures 124 in the memory region 126 and the logic region in the first portion of the interconnect layer 104 of the semiconductor device 100.

In some implementations, the first portion of the interconnect layer 104 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and the layer 118a (e.g., the M0 layer) of metallization structures 122 may be formed in the ILD layer 114 and the ESL 116 (e.g., using one or more deposition tools and/or one or more planarization tools). Another ILD layer 114 and another ESL 116 may be formed, and the layer 120a (e.g., the V0 layer) of interconnect structures 124 may be formed in the ILD layer 114 and the ESL 116. The layers 118b-118g, and 120b-120f may be formed in a similar manner.

One or more deposition tools may be used to deposit the metallization structures 122 and/or the interconnect structures 124 using a PVD technique, an ALD technique, a CVD technique, an electroplating technique (e.g., an electro-chemical plating technique), and/or another suitable deposition technique. In some implementations, a planarization tool may be used to planarize the metallization structures 122 and/or the interconnect structures 124 after the metallization structures 122 and/or the interconnect structures 124 are deposited.

As shown in FIG. 2D, a second portion of the interconnect layer 104 of the semiconductor device 100 is formed above the first portion of the interconnect layer 104. The second portion includes the layer 120d (e.g., the V3 layer) and the layer 118e (e.g., the M4 layer). The layers 120d and 118e are formed in the logic region 128 in an ILD layer 114 (e.g., ILD layer 114b) over the layer 120c (e.g., the V2 layer) and the layer 118d (e.g., the M3 layer). The layers 120d and 118e are formed in the logic region 128 before the memory devices 132a-132c and the bottom interconnect structures 144 of the semiconductor structure 130 are formed in the memory region 126. The layers 120d and 118e in the logic region 128 may be formed in a similar manner to the layers 120a-120c, and the layers 118a-118d.

As shown in FIG. 2E, the memory devices 132a-132c and the bottom interconnect structures 144 of the semiconductor structure 130 are formed in the memory region 126 after the layers 120d and 118e are formed in the logic region 128. The bottom interconnect structures 144 are formed in the memory region 126 on a lateral side of the logic region 128 in the x-direction. A lower part of the bottom interconnect structures 144 is formed in the same ILD layer 114 (e.g., ILD layer 114b) as the layers 120d and 118e, and an upper part of the bottom interconnect structures 144 is formed in an ILD layer 114 (e.g., ILD layer 114c) disposed over the ILD layer 114 in which the layers 120d and 118e are formed. The bottom electrode layer 134, the MTJ structure 136, and the top electrode layer 138 of each of the memory devices 132a-132c are formed over the bottom interconnect structures 144.

The memory devices 132a-132c may be formed on and/or in one or more ILD layers 114 and/or one or more ESLs 116 in the interconnect layer 104. The memory devices 132a-132c may be formed such that the bottom electrode layers 134 of the memory devices 132a-132c land on the bottom interconnect structures 144 in the interconnect layer 104.

As shown in FIG. 2F, a metallization structure 122 (e.g., metallization structure 122h) is formed in the memory region 126 in an ILD layer 114 (e.g., ILD layer 114c) on the top electrode layer 138 of each memory device 132a-132c. The metallization structure 122 is in direct contact with curved top surfaces of each of the top electrode layers 138. In addition, layers 120e and 118f are formed in the logic region 128 in an ILD layer 114 (e.g., ILD layer 114c) over the layers 120d (e.g., the V3 layer) and the layer 118e (e.g., the M4 layer). The layers 120e and 118f in the logic region 128 may be formed in a similar manner to the layers 120a-120d, and the layers 118a-118e.

As shown in FIG. 2G, a remaining part of the second portion of the interconnect layer 104 of the semiconductor device 100 (e.g., layers 118g and 120f) is formed in the memory region 126 and in the logic region 128 above layers 118f and 120e and/or above the memory devices 132a-132c. The layers 120f and 118g may be formed in a similar manner to the layers 120a-120e, and the layers 118a-118f.

As indicated above, FIGS. 2A-2G are provided as an example. Other examples may differ from what is described with regard to FIGS. 2A-2G.

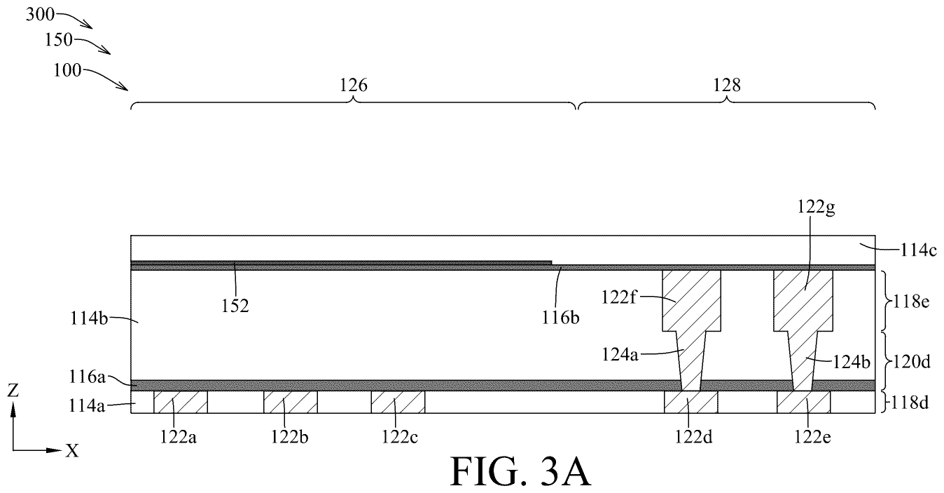

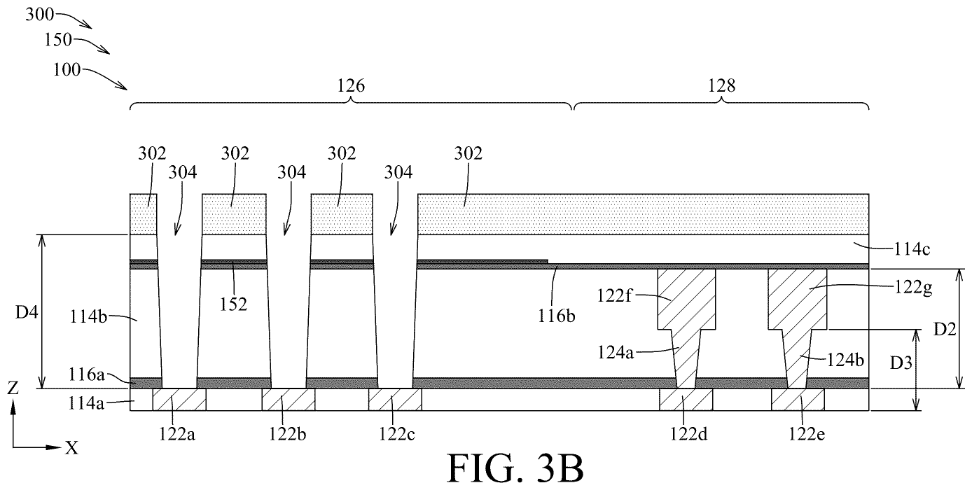

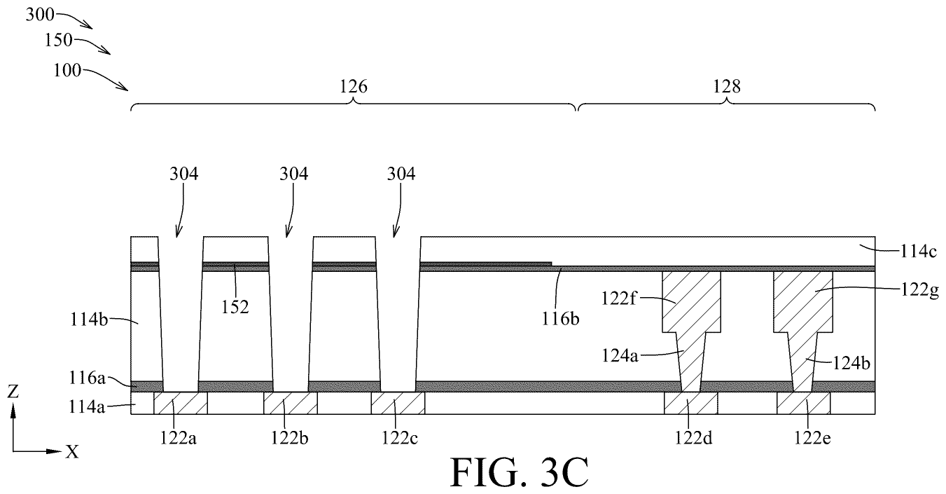

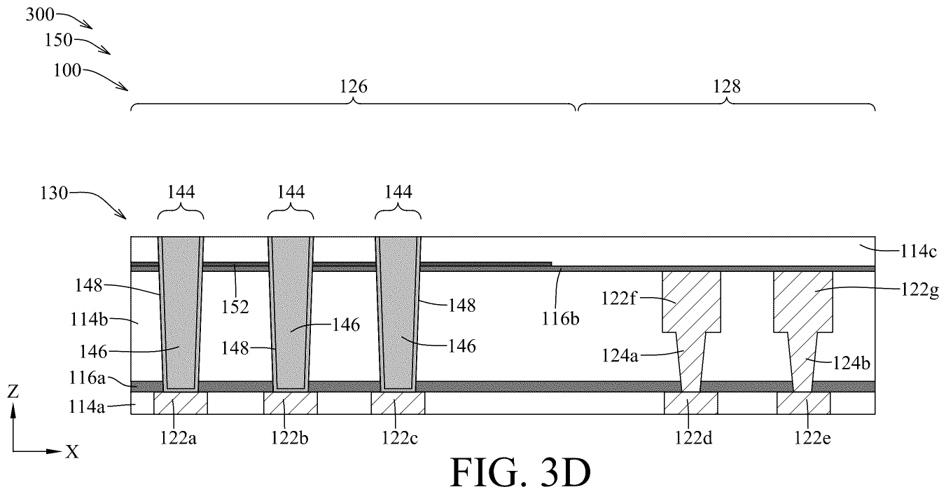

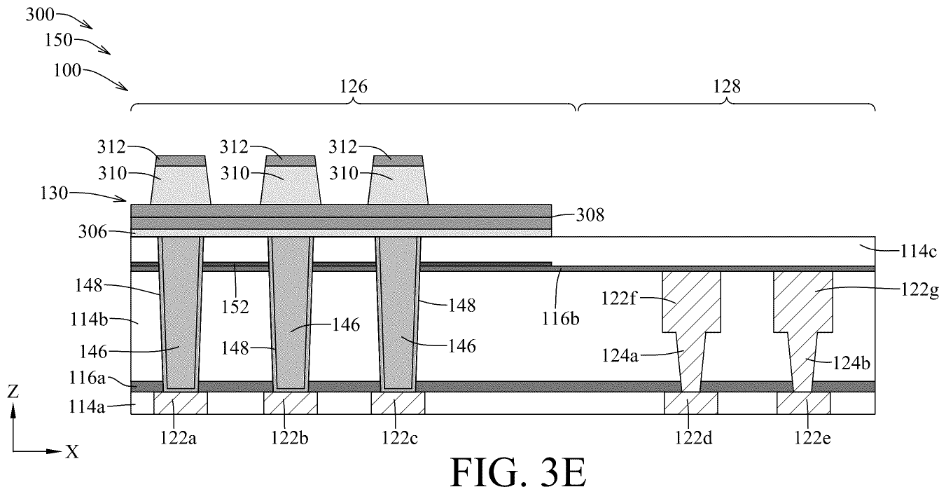

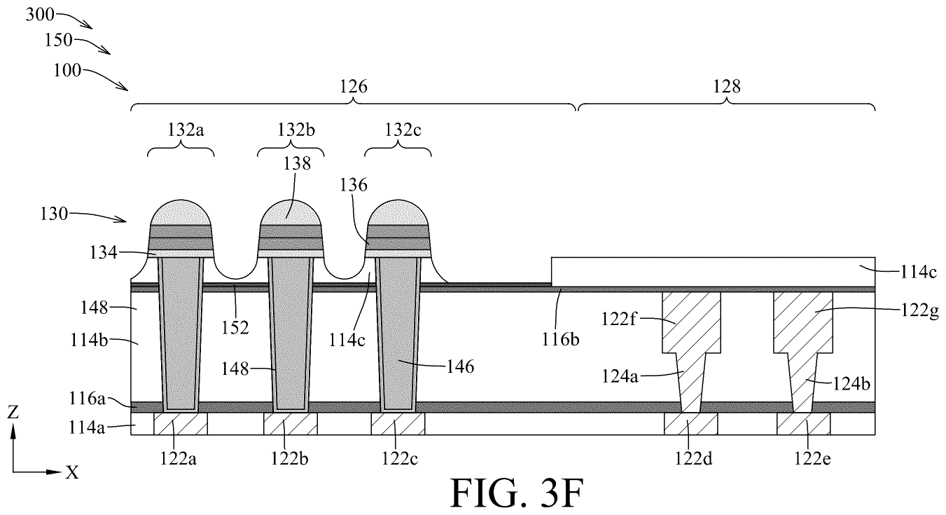

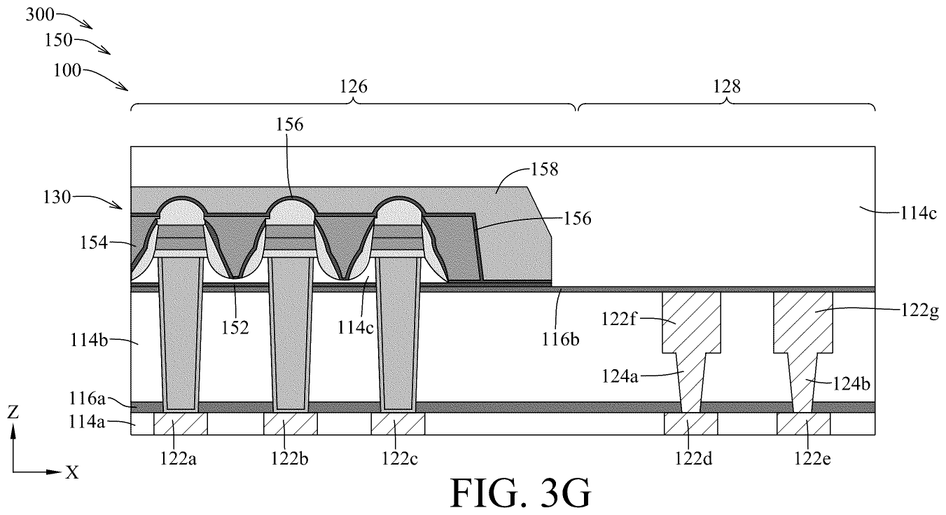

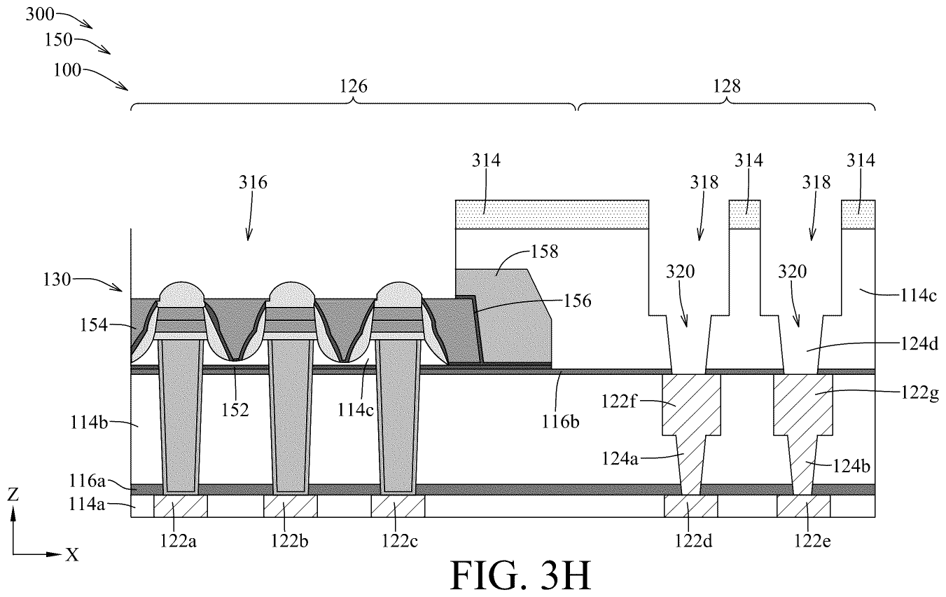

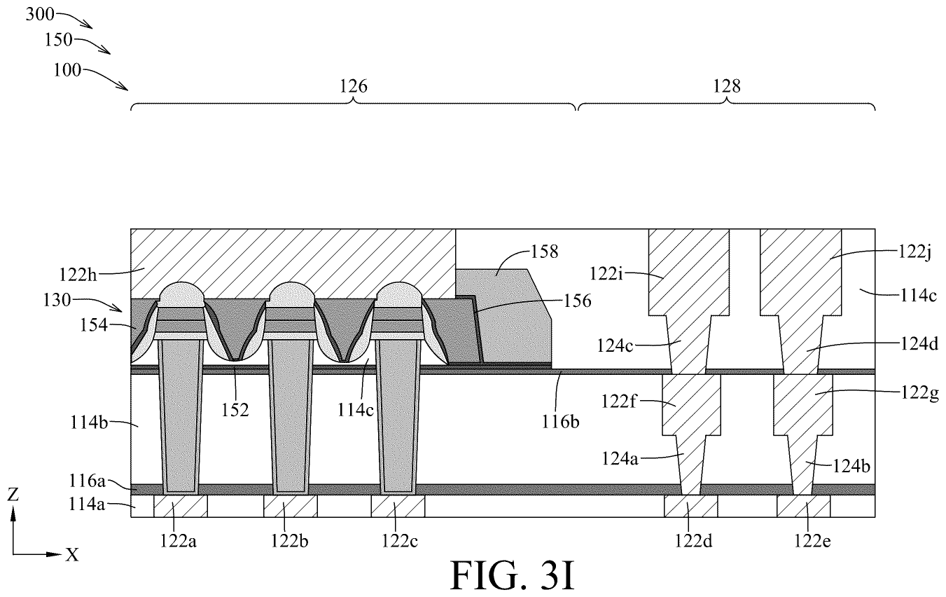

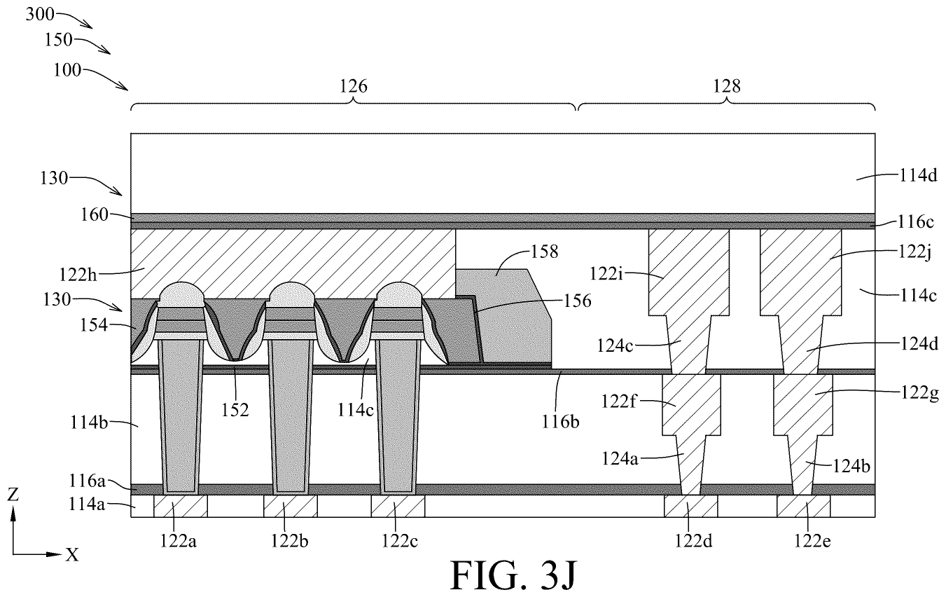

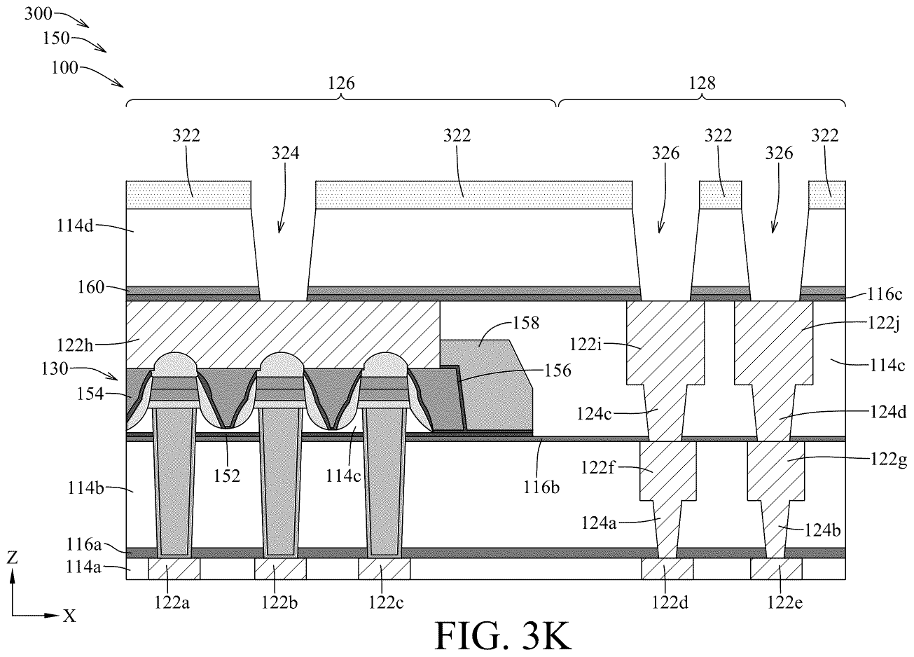

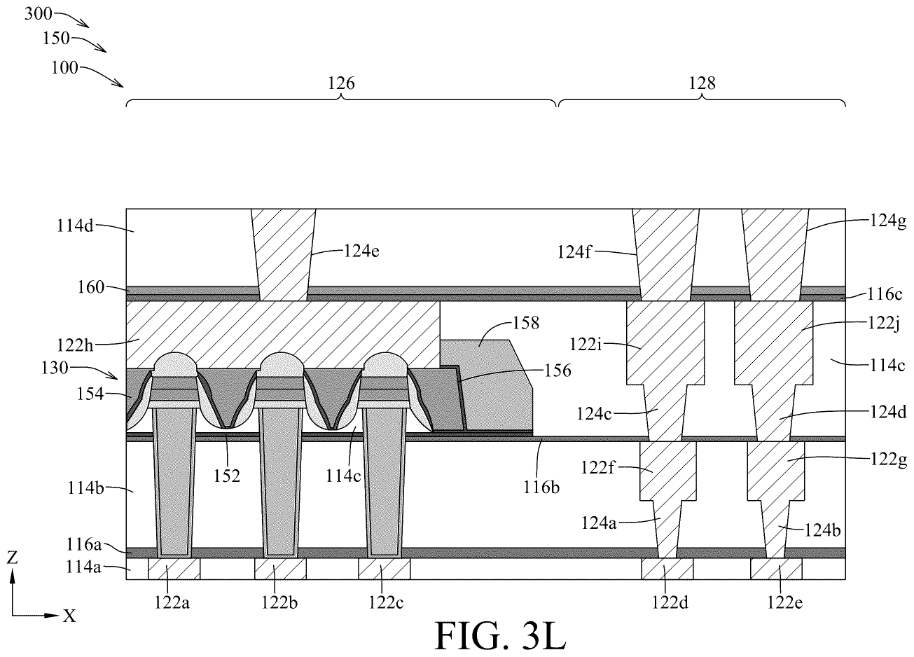

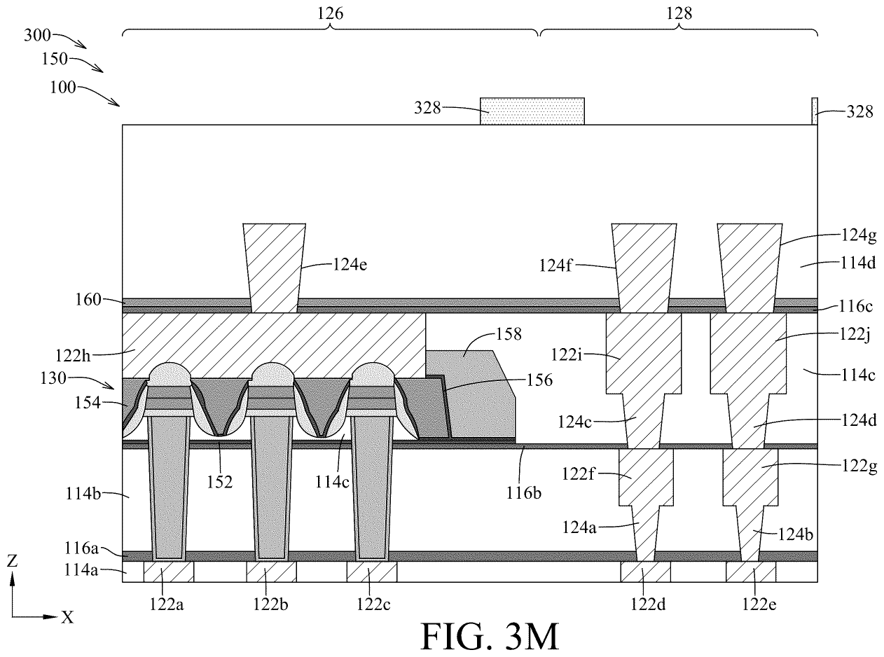

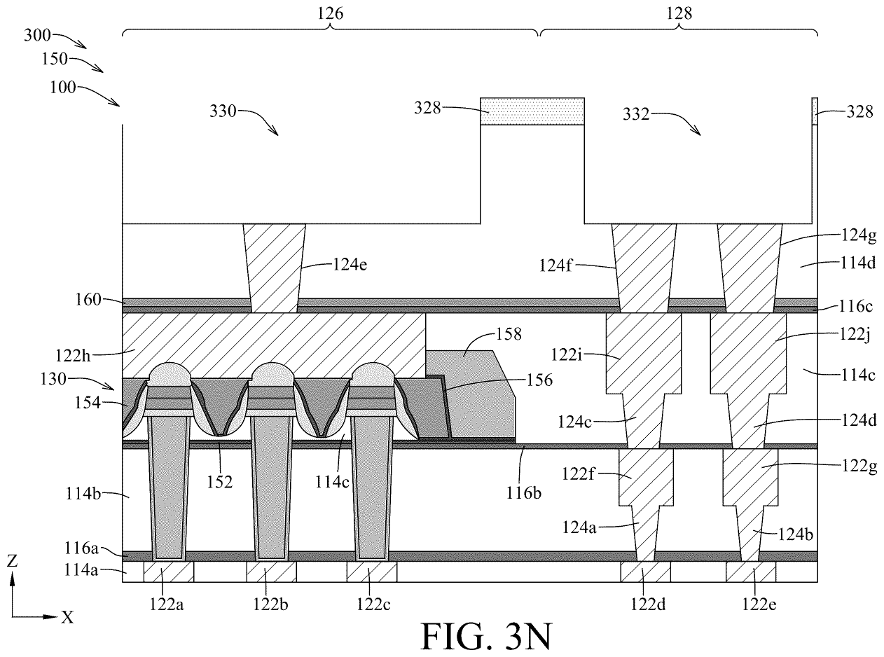

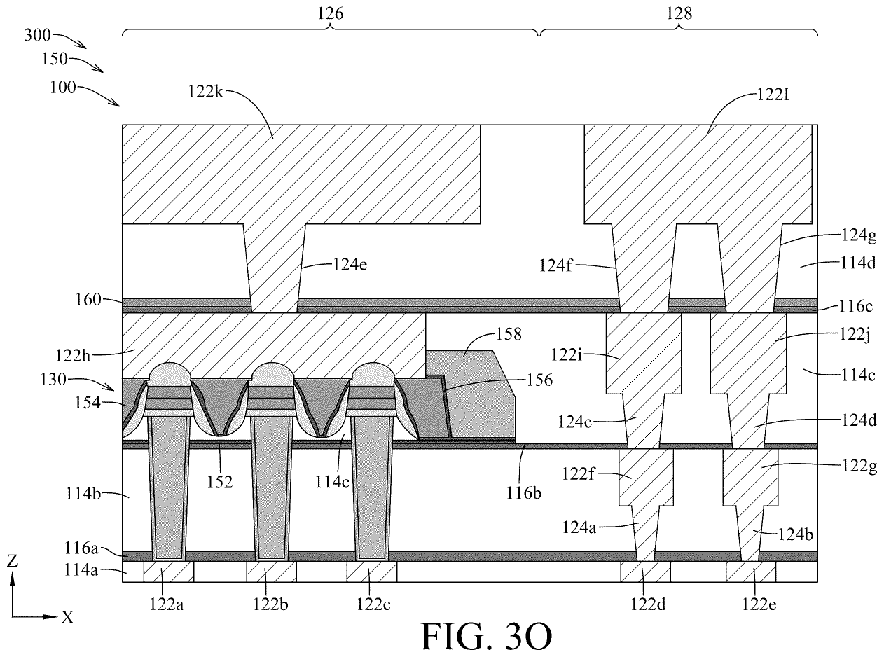

FIGS. 3A-3O are diagrams of an example implementation 300 of forming a portion of a semiconductor device 100 described herein. In some implementations, one or more of the semiconductor processing operations described in connection with FIGS. 3A-3O may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 3A-3O may be performed as part of the process for forming the semiconductor device 100 described in connection with FIGS. 2A-2G.

As shown in FIG. 3A, the layer 120d (e.g., the V3 layer), including the interconnect structures 124a and 124b, and the layer 118e (e.g., the M4 layer), including the metallization structures 122f and 122g, are formed in the logic region 128 in the ILD layer 114b over the layer 118d (e.g., the M3 layer) including the metallization structures 122a-122e. The layers 120d and 118e are formed in the logic region 128 before the memory devices 132a-132c and the bottom interconnect structures 144 of the semiconductor structure 130 are formed in the memory region 126. Recesses may be formed in and/or through the ILD layer 114b and the ESL 116 (e.g., using an exposure tool, a developer tool, and/or an etch tool), and the layers 120d and 118e may be formed in the ILD layer 114b and the ESL 116a (e.g., using one or more deposition tools and/or one or more planarization tools). The one or more deposition tools may be used to deposit the interconnect structures 124a and 124b and the metallization structures 122f and 122g in the recesses using a PVD technique, an ALD technique, a CVD technique, an electroplating technique (e.g., an electro-chemical plating technique), and/or another suitable deposition technique. In some implementations, a planarization tool may be used to planarize the metallization structures 122f and 122g and/or the interconnect structures 124a and 124b after the metallization structures 122f and 122g and/or the interconnect structures 124a and 124b are deposited. The interconnect structures 124a and 124b are formed through the ESL 116a to be in direct contact with the underlying metallization structures 122d and 122e.

An ESL 116b is formed over the ILD layer 114b in the memory region 126 and in the logic region 128. The oxide layer 152 (e.g., an aluminum oxide (AlₓO_{y}) layer) may be disposed on the ESL 116b in the memory region 126. Another ILD layer 114c is disposed over the oxide layer and ESL 116b in the memory region 126, and over the ESL 116b in the logic region 128. The ESL 116b, the oxide layer 152, and the ILD layer 114c may be deposited using a PVD technique, an ALD technique, a CVD technique, an oxidation technique, and/or another suitable deposition technique. In some implementations, a planarization tool may be used to planarize the ESL 116b, the oxide layer 152, and/or the ILD layer 114c after ESL 116b, the oxide layer 152, and/or the ILD layer 114c are deposited.

As shown in FIG. 3A, a masking layer may be formed on the ILD layer 114c in the interconnect layer 104 of the semiconductor device 100. For example, a dielectric masking layer 302 may be formed on the ILD layer 114c. The dielectric masking layer 302 may include a silicon oxynitride material (SiON) and/or another suitable dielectric material.

A deposition tool may be used to deposit the dielectric masking layer 302 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 302 after the dielectric masking layer 302 is deposited.

A photoresist layer may be formed above the dielectric masking layer 302, and a pattern may be formed in the photoresist layer. A deposition tool may be used to form the photoresist layer on the dielectric masking layer 302 (e.g., using a spin-coating technique or another suitable deposition technique). In some implementations, a bottom antireflective coating (BARC) is first deposited on the dielectric masking layer 302, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 302 based on the pattern in the photoresist layer, to transfer the pattern to the dielectric masking layer 302. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 302 compared to the material of the underlying ILD layer 114c. Thus, the etch operation may stop on the ILD layer 114c with minimal etching to the ILD layer 114c.

As shown in FIG. 3B, another etch operation is performed to etch through the ILD layers 114b, 114c, through the oxide layer 152, and through the ESLs 116b and 116a to form recesses 304. The etch operation may include, for example, a gas-based etch operation in which a different type of etchant is used, as compared to the etchant that was used to transfer the pattern to the dielectric masking layer 302. Thus, the semiconductor device 100 may be transferred from a first etch tool (in which the pattern was transferred to the dielectric masking layer 302) to a second etch tool (in which the ILD layers 114b, 114c, the oxide layer 152, and the ESLs 116b and 116a are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

The gas-based etchant that is used to etch the ILD layers 114c, 114b, the oxide layer 152, and the ESLs 116b, 116a, may include a fluorine-based gas etchant that has a higher etch rate for the dielectric materials of the ILD layers 114c, 114b, the oxide layer 152, and the ESLs 116b, 116a, compared to the etch rate of the dielectric masking layer 302. This enables the ILD layers 114c, 114b, the oxide layer 152, and the ESLs 116b, 116a, to be etched with minimal etching to the dielectric masking layer 302 (and thus, minimal to no increase in the width or critical dimension at the tops of the recesses 304). The fluorine-based etchant may include a carbon fluoride-based (CFₓ) gas etchant such as a carbon tetrafluoride (CF₄) gas etchant.

In some implementations, a plurality of etch operations (e.g., a plurality of gas-based etch operations using the fluorine-based etchant) are performed to form the recesses 304. For example, a first etch operation (referred to as a “main etch” operation) may be performed to form the recesses 304 to the ESL 116a. In other words, etching in the first etch operation stops at the ESL 116a such that the ESL 116a remains between the bottom of the recesses 304 and the underlying metallization structures 122a, 122b, and 122c. The ESL 116a is kept over the metallization structures 122a, 122b, and 122c to prevent the metallization structures 122a, 122b, and 122c from being exposed to oxygen and other contaminants that might otherwise result in oxidation of the metallization structures 122a, 122b, and 122c. After the first etch operation, the recesses 304 may have tapered sidewalls, resulting in the lateral width of the recesses 304 decreasing from the tops of the recesses 304 to the bottoms of the recesses 304.

A second etch operation (referred to as an “over etch” operation) may be performed after the first etch operation to shape the bottom portions of the recesses 304. In particular, the second etch operation may be performed to increase the verticality of the sidewalls of the recesses 304, thereby lessening the taper in the sidewalls of the recesses 304. The dielectric masking layer 302 remains on the ILD layer 114c during the first and second etch operations to form and shape the recesses 304 such that the dielectric masking layer 302 protects the ILD layer 114c from being etched.

A third etch operation (referred to as a “linear removal” etch operation) may be performed to etch through the ESL 116a at the bottom of the recesses 304 to extend the recesses 304 through the ESL 116a and to the underlying metallization structures 122a, 122b, and 122c. Thus, the metallization structures 122a, 122b, and 122c are exposed through the recesses 304 after the third etch operation. The third etch operation may be performed using the second etch tool and using a fluorine-based etchant such as a carbon fluoride-based (CFₓ such as CF₄) gas etchant. The dielectric masking layer 302 remains on the ILD layer 114c during the third etch operation to etch through the ESL 116a such that the dielectric masking layer 302 protects the ILD layer 114c from being etched, which reduces the likelihood of critical dimension reduction. As shown in FIG. 3C, following exposure of the metallization structures 122a, 122b, and 122c in the recesses 304, the dielectric masking layer 302 is removed from the ILD layer 114c.

In some implementations, an aspect ratio (e.g., ratio of vertical (z-direction) dimension to horizontal (x-direction) dimension) of each of the recesses 304 is greater than or equal to approximately 5. As noted herein, a vertical dimension (e.g., height or depth) of bottom electrode vias (e.g., bottom interconnect structures 144) for memory devices is increased in comparison to vertical dimensions of bottom electrode vias of other memory devices. As a result of the increased vertical dimension, the same etching operation may be used to form the recesses 304 for the bottom interconnect structures 144 and to form alignment mark recesses having a sufficient depth. The vertical dimension D4 (e.g., depth) of the recesses 304 provides for a desired alignment mark recess depth without having to perform additional etching and use additional etch masks to form a remainder of an alignment mark recess. If the aspect ratio of each of the recesses 304 is smaller than 5, then the geometry of the recesses 304 will not provide sufficient topography for an adjacent alignment mark region, so that additional etching and another mask will be needed to form a remainder of a recess in an alignment mark region. In addition, an aspect ratio of each of the recesses 304 that is smaller than 5 may result in wider bottom interconnect structures 144 (e.g., greater x-direction dimension), which consumes more chip area. However, other aspect ratio values and ranges are within the scope of this disclosure.

A vertical dimension D4 (e.g., z-direction dimension) (e.g., depth) of each recess 304 is greater than a combined vertical dimension D2 (e.g., z-direction dimension) of the interconnect structure 124a and the metallization structure 122f (or of the interconnect structure 124b and the metallization structure 122g). The vertical dimension D4 of each recess 304 is greater than a combined vertical dimension D3 (e.g., z-direction dimension) of the interconnect structure 124b and the metallization structure 122e (or of the interconnect structure 124a and the metallization structure 122d).

In some implementations, the vertical dimension D4 may be included in the range of approximately 1100 angstroms to approximately 1400 angstroms. As noted herein, a vertical dimension (e.g., height or depth) of bottom electrode vias (e.g., bottom interconnect structures 144) for memory devices is increased in comparison to vertical dimensions of bottom electrode vias of other memory devices. As a result of the increased vertical dimension, the same etching operation may be used to form the recesses 304 for the bottom interconnect structures 144 and to form alignment mark recesses having a sufficient depth. The depth of the recesses 304 provides for a desired alignment mark recess depth without having to perform additional etching and use additional etch masks to form a remainder of an alignment mark recess. If the vertical dimension D4 of each of the recesses 304 is smaller than 1100 angstroms, then the vertical dimension D4 of the recesses 304 will not provide sufficient topography for an adjacent alignment mark region, so that additional etching and another mask will be needed to form a remainder of a recess in an alignment mark region. If the vertical dimension D4 is greater than 1400 angstroms, taller/deeper bottom interconnect structures 144 (e.g., greater z-direction dimension) may consume more chip area. In addition, bottom interconnect structures 144 which are too tall/deep may have electrical conductivity issues and/or exhibit increased resistance. However, other values and ranges are within the scope of this disclosure.

As shown in FIG. 3D, the liner layer 148 may be deposited on the sidewalls and on the bottom surfaces of the recesses 304. The bottom surfaces of the recesses 304 correspond to the top surfaces of the metallization structures 122a, 122b, and 122c, and thus the liner layer 148 may be in physical contact with the top surfaces of the metallization structures 122a, 122b, and 122c. The liner layer 148 may also be deposited on the top surface of the ILD layer 114c between adjacent recesses 304, and removed from the top surface of the ILD layer 114c in a subsequent CMP operation. In some implementations, a deposition tool is used to conformally deposit the liner layer 148 such that the liner layer 148 conforms to the profile of the recesses 304. In some implementations, a conformal CVD technique and/or an ALD technique is used to deposit the liner layer 148.

The fill layer 146 may be deposited on the liner layer 148. The fill layer 146 may be deposited such that the fill layer 146 fills the remaining areas of the recesses 304. The fill layer 146 may also be deposited on the top surface of the liner layer 148 between recesses 304, and removed along with the liner layer 148 from the top surface of the ILD layer 114c in a subsequent CMP operation. In some implementations, a deposition tool is used to deposit the fill layer 146 using a PVD technique, a CVD technique, an ALD technique, and/or another suitable deposition technique to form the bottom interconnect structures 144 including the fill layers 146 and the liner layers 148.

As shown in FIG. 3E, in some implementations, a blanket bottom electrode layer 306 is deposited on the bottom interconnect structures 144 and on portions of the ILD layer 114c in which the bottom interconnect structures 144 may be formed. A deposition tool may be used to deposit the blanket bottom electrode layer 306 using a CVD technique, a PVD technique, an ALD technique, an electroplating technique, and/or another suitable deposition technique. The material of the blanket bottom electrode layer 306 may be deposited in one or more deposition operations. In some implementations, a seed layer is first deposited, and the material of the blanket bottom electrode layer 306 is deposited on the seed layer. In some implementations, a planarization tool is used to perform a planarization operation (e.g., a CMP operation) to planarize the blanket bottom electrode layer 306 after the blanket bottom electrode layer 306 is deposited. The blanket bottom electrode layer 306 may include one or more electrically conductive materials to be used for the bottom electrode layers 134. Examples include metals such as molybdenum (Mo), nickel (Ni), iridium (Ir), and chromium (Cr), as well as metal nitrides such as titanium nitride (TiN) or tantalum nitride (TaN), among other examples.

As further shown in FIG. 3E, a deposition tool may form a blanket MTJ structure 308 over and/or on the top surface of the blanket bottom electrode layer 306. In some implementations, a deposition tool forms the blanket MTJ structure 308 using a spin-coating technique, a CVD technique, a PVD technique, an ALD technique, and/or another deposition technique. In some implementations, a planarization tool is used to perform a planarization operation (e.g., a CMP operation) to planarize the blanket MTJ structure 308 after the blanket MTJ structure 308 is deposited. The blanket MTJ structure 308 may include ferromagnetic layers separated by a tunnel barrier layer. The ferromagnetic layers may include ferrous materials including a combination of iron (Fe) and one or more of cobalt (Co), boron (B), and/or nickel (Ni), among other examples, and the tunnel barrier layer may include a crystalline material, such as magnesium oxide (MgO) and/or another suitable material.

As further shown in FIG. 3E, a deposition tool may form a plurality of mask structures, including a top electrode mask layer 310 and a dielectric mask layer 312 on the top electrode mask layer 310, over and/or on the top surface of the blanket MTJ structure 308. The plurality of mask structures, each including the top electrode mask layer 310 and the dielectric mask layer 312 on the top electrode mask layer 310, are spaced apart from each in the x-direction. In some implementations, a deposition tool forms the plurality of mask structures using a spin-coating technique, a CVD technique, a PVD technique, an ALD technique, and/or another deposition technique. The top electrode mask layer 310 may include one or more electrically conductive materials to be used for the top electrode layers 138. Examples include metals such as molybdenum (Mo), nickel (Ni), iridium (Ir), and chromium (Cr), as well as metal nitrides such as titanium nitride (TiN) or tantalum nitride (TaN), among other examples.

In some implementations, the dielectric mask layer 312 includes tetraethyl orthosilicate (TEOS) or another suitable dielectric material.

As shown in FIG. 3F, portions of the blanket MTJ structure 308 and the blanket bottom electrode layer 306 are removed in one or more etching processes, where the plurality of mask structures, each including a top electrode mask layer 310 and a dielectric mask layer 312 on the top electrode mask layer 310, are used as masks that cover portions of the blanket MTJ structure 308 and underlying portions of the blanket bottom electrode layer 306. Exposed portions of the blanket MTJ structure 308 and of the blanket bottom electrode layer 306 that are not covered by the plurality of mask structures are removed in the one or more etching processes to pattern the blanket MTJ structure 308 into the MTJ structures 136 and to pattern the blanket bottom electrode layer 306 into the bottom electrode layers 134. In addition, the one or more etching processes result in removal of the dielectric mask layers 312, and patterning of the top electrode mask layers 310 into the top electrode layers 138 each having a curved top surface. In some implementations, an etch tool uses a wet etch technique, a dry etch technique, a plasma-enhanced etch technique, and/or another type of etch technique to perform the one or more etching processes.

The resulting patterned MTJ structures 136 and patterned bottom electrode layers 134 each include angled side surfaces, such that the MTJ structures 136 and bottom electrode layers 134 each taper to a larger width (e.g., x-direction dimension) in the downward z-direction. The one or more etching processes cause removal of portions of the ILD layer 114c between and/or adjacent to the memory devices 132a-132c to result in a curved profile of the top surfaces of the portions of the ILD layer 114c between and/or adjacent to the memory devices 132a-132c.

As shown in FIG. 3G, the first and second spacer layers 140 and 142 are formed on side surfaces of the bottom electrode layer 134, the MTJ structure 136, and a lower portion of the top electrode layer 138 for each of the memory devices 132a-132c. The first and second spacer layers 140 and 142 are further formed on the top surfaces of the portions of the ILD layer 114c between and/or adjacent to the memory devices 132a-132c.

In some implementations, the first and second spacer layers 140 and 142 are conformally deposited on exposed side surfaces of the bottom electrode layers 128, on exposed side surfaces of the MTJ structures 136, on exposed side and top surfaces of the top electrode layers 138, and on the top surfaces of the portions of the ILD layer 114c between and/or adjacent to the memory devices 132a-132c. A deposition tool may be used to deposit the first and second spacer layers 140 and 142 using an ALD technique, a CVD technique, and/or another suitable deposition technique. An etch tool performs an etch process to remove central portions of the first and second spacer layers 140 and 142 on the top surfaces of the top electrode layers 138.

The ALD oxide layer 154 is deposited around the memory devices 132a-132c on the second spacer layers 142. A deposition tool may be used to deposit the ALD oxide layer 154 using an ALD technique. The layer 156 is deposited on exposed surfaces of the ALD oxide layer 154 and on exposed surfaces of the top electrode layers 138. A deposition tool may be used to deposit the layer 156 using an ALD technique, a CVD technique, and/or another suitable deposition technique. The PEALD oxide layer 158 is deposited on the layer 156 and over the oxide layer 152 and a portion of the ESL 116b in the memory region 126. A deposition tool may be used to deposit the PEALD oxide layer 158 using a PEALD technique.

An additional portion of the ILD layer 114c is deposited on the PEALD oxide layer 158 and on an underlying portion of the ILD layer 114c in the memory and logic regions 126 and 128. A deposition tool may be used to deposit the additional portion of the ILD layer 114c using a PVD technique, an ALD technique, a CVD technique, an oxidation technique, and/or another suitable deposition technique.

As shown in FIG. 3H, following deposition of the additional portion of the ILD layer 114c, a dielectric masking layer 314 is deposited on top surfaces of the ILD layer 114c. A deposition tool may be used to deposit the dielectric masking layer 314 using a PVD technique, an ALD technique, a CVD technique, an oxidation technique, and/or another suitable deposition technique.

A photoresist layer may be formed above the dielectric masking layer 314, and a pattern may be formed in the photoresist layer. A deposition tool may be used to form the photoresist layer on the dielectric masking layer 314 (e.g., using a spin-coating technique or another suitable deposition technique). In some implementations, a BARC is first deposited on the dielectric masking layer 314, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 314 based on the pattern in the photoresist layer, to transfer the pattern to the dielectric masking layer 314. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 314 compared to the material of the underlying ILD layer 114c. Thus, the etch operation may stop on the ILD layer 114c, with minimal etching to the ILD layer 114c.

One or more additional etch operations may be performed to etch through the ILD layer 114c, through the PEALD oxide layer 158, and through the layer 156 to form a recess 316 in the memory region 126 where the curved top surfaces of the top electrode layers 138 are exposed. The one or more additional etch operations also etch through the ILD layer 114c and the ESL 116b to form recesses 318 and 320 in the logic region 128, where bottom surfaces of the recesses 320 expose portions of top surfaces of the underlying metallization structures 122f and 122g. The etch operations may include, for example, a gas-based etch operation in which a different type of etchant is used, as compared to the etchant that was used to transfer the pattern to the dielectric masking layer 314. Thus, the semiconductor device 100 may be transferred from a first etch tool (in which the pattern was transferred to the dielectric masking layer 314) to a second etch tool (in which the ILD layer 114c, the PEALD oxide layer 158, the layer 156, and the ESL 116b are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

In some implementations, a dual damascene process is used to form the recesses 318 and 320. For example, the recesses 320 may be formed in and/or through a bottom portion of the ILD layer 114c and ESL 116b. The recesses 318 may be formed in the top portion of the ILD layer 114c above the recesses 320.

An interconnect structure-first dual damascene procedure can be performed in which the recesses 318 and 320 are formed by forming the recesses 320 before forming the recesses 318. In some implementations, a trench-first dual damascene procedure can be performed in which the recesses 318 and 320 are formed by forming the recesses 318 before forming the recesses 320.

As shown in FIG. 3I, one or more deposition tools may be used to deposit conductive material in the recesses 316, 318, and 320 to form the metallization structures 122h, 122i, and 122j, and the interconnect structures 124c and 124d, using a PVD technique, an ALD technique, a CVD technique, an electroplating technique (e.g., an electro-chemical plating technique), and/or another suitable deposition technique. As noted herein, the conductive material to form the metallization structures 122h, 122i, and 122j and the interconnect structures 124c and 124d may include, for example, tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included in the metallization structures 122h, 122i, and 122j and the interconnect structures 124c and 124d. The one or more liner layers may include barrier liners, adhesion liners, and/or another type of liners. Examples of materials for the one or more liners include tantalum nitride (TaN) and/or titanium nitride (TiN), among other examples. A planarization tool may be used to planarize the surface of the ILD layer 114c to remove the dielectric masking layer 314, and excess portions of the conductive material formed on the dielectric masking layer 314 and/or over the top surfaces of the ILD layer 114c. The metallization structure 122h is commonly connected to and in physical contact with the top electrode layers 138 of each of the memory devices 132a-132c.

As shown in FIG. 3J, another ESL 116c is deposited over the ILD layer 114c, the dielectric layer 160 is deposited on the ESL 116c, an additional ILD layer 114d is deposited on the dielectric layer 160. A deposition tool may be used to deposit the ESL 116c, the dielectric layer 160, and the ILD layer 114d using a PVD technique, an ALD technique, a CVD technique, an oxidation technique, and/or another suitable deposition technique.

As shown in FIG. 3K, a dielectric masking layer 322 may be formed on the ILD layer 114d. The dielectric masking layer 322 may include a silicon oxynitride material (SiON) and/or another suitable dielectric material. A deposition tool may be used to deposit the dielectric masking layer 322 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 322 after the dielectric masking layer 322 is deposited.

A photoresist layer may be formed above the dielectric masking layer 322, and a pattern may be formed in the photoresist layer. A deposition tool may be used to form the photoresist layer on the dielectric masking layer 322 (e.g., using a spin-coating technique or another suitable deposition technique). In some implementations, a BARC is first deposited on the dielectric masking layer 322, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 322 based on the pattern in the photoresist layer, to transfer the pattern to the dielectric masking layer 322. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 322 compared to the material of the underlying ILD layer 114d. Thus, the etch operation may stop on the ILD layer 114d with minimal etching to the ILD layer 114d.

Another etch operation may be performed to etch through the ILD layer 114d, the dielectric layer 160, and through the ESL 116c to form a recess 324 and recesses 326, where a bottom surface of the recess 324 exposes a portion of the top surface of the underlying metallization structure 122h, and where bottom surfaces of the recesses 326 expose portions of the top surfaces of the metallization structures 122i and 122j. The etch operation may include, for example, a gas-based etch operation in which a different type of etchant is used, as compared to the etchant that was used to transfer the pattern to the dielectric masking layer 322. Thus, the semiconductor device 100 may be transferred from a first etch tool (in which the pattern was transferred to the dielectric masking layer 322) to a second etch tool (in which the ILD layer 114d, the dielectric layer 160, and the ESL 116c are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

As shown in FIG. 3L, one or more deposition tools may be used to deposit the conductive material of the interconnect structures 124e, 124f, and 124g using a PVD technique, an ALD technique, a CVD technique, an electroplating technique (e.g., an electro-chemical plating technique), and/or another suitable deposition technique. In some implementations, a planarization tool may be used to planarize the interconnect structures 124e, 124f, and 124g and a top surface of the ILD layer 114d to remove remaining portions of the photoresist layer, the dielectric masking layer 322, and/or the conductive material of the interconnect structures 124e, 124f, and 124g on the top surface of the ILD layer 114d after the interconnect structures 124e, 124f, and 124g are deposited.

As shown in FIG. 3M, an additional portion of the ILD layer 114d is deposited over the interconnect structures 124e-124g and on an underlying portion of the ILD layer 114d in the memory and logic regions 126 and 128. A deposition tool may be used to deposit the additional portion of the ILD layer 114d using a PVD technique, an ALD technique, a CVD technique, an oxidation technique, and/or another suitable deposition technique.

As further shown in FIG. 3M, a dielectric masking layer 328 may be formed on the ILD layer 114d. The dielectric masking layer 328 may include a silicon oxynitride material (SiON) and/or another suitable dielectric material. A deposition tool may be used to deposit the dielectric masking layer 328 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 328 after the dielectric masking layer 328 is deposited.

A photoresist layer may be formed above the dielectric masking layer 328, and a pattern may be formed in the photoresist layer. A deposition tool may be used to form the photoresist layer on the dielectric masking layer 328 (e.g., using a spin-coating technique or another suitable deposition technique). In some implementations, a BARC is first deposited on the dielectric masking layer 328, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 328 based on the pattern in the photoresist layer, to transfer the pattern to the dielectric masking layer 328. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 328 compared to the material of the underlying ILD layer 114d. Thus, the etch operation may stop on the ILD layer 114d with minimal etching to the ILD layer 114d.

As shown in FIG. 3N, another etch operation may be performed to etch through the ILD layer 114d to form a recess 330 and a recesses 332, where a bottom surface of the recess 330 exposes a portion of the top surface of the underlying interconnect structure 124e, and where a bottom surface of the recess 332 exposes portions of the top surfaces of the interconnect structures 124f and 124g. The etch operation may include, for example, a gas-based etch operation in which a different type of etchant is used, as compared to the etchant that was used to transfer the pattern to the dielectric masking layer 328. Thus, the semiconductor device 100 may be transferred from a first etch tool (in which the pattern was transferred to the dielectric masking layer 328) to a second etch tool (in which the ILD layer 114d is etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

As shown in FIG. 3O, one or more deposition tools may be used to deposit the conductive material of the metallization structures 122k and 122l using a PVD technique, an ALD technique, a CVD technique, an electroplating technique (e.g., an electro-chemical plating technique), and/or another suitable deposition technique. In some implementations, a planarization tool may be used to planarize the metallization structures 122k and 122l and a top surface of the ILD layer 114d to remove remaining portions of the photoresist layer, the dielectric masking layer 328, and/or the conductive material of the metallization structures 122k and 122l on the top surface of the ILD layer 114d after the metallization structures 122k and 122l are deposited.

As indicated above, FIGS. 3A-3O are provided as an example. Other examples may differ from what is described with regard to FIGS. 3A-3O.

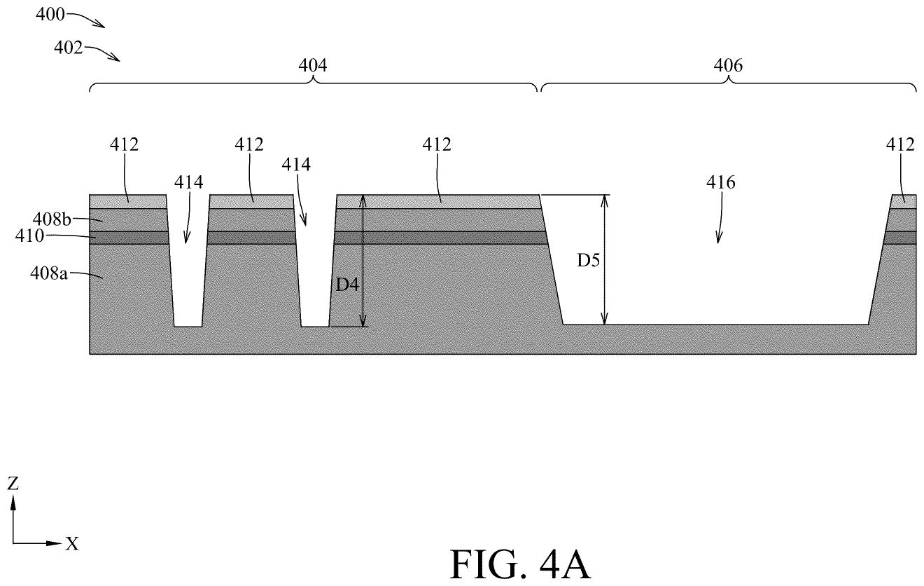

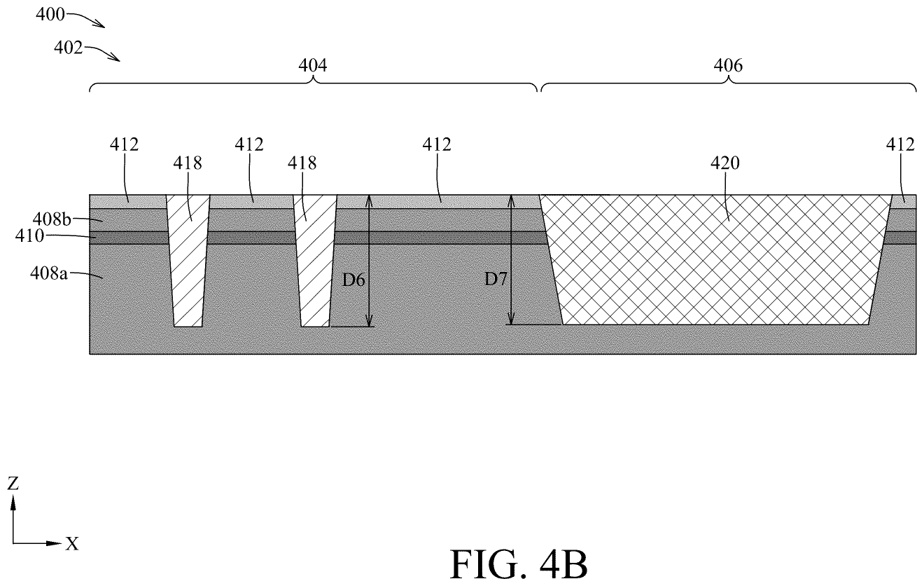

FIGS. 4A and 4B are diagrams of an example implementation 400 of forming a portion of a semiconductor device 402 described herein. The semiconductor device 402 is similar to the semiconductor device 100, and includes a memory region 404 and alignment mark region 406 on a side of the memory region 404 in the x-direction. In some cases, the alignment mark region 406 may be disposed between the memory region 404 and a logic region (not shown). The memory region 404 may be the same as or similar to the memory region 126 of the semiconductor device 100, and the logic region (not shown) may be the same as or similar to the logic region 128 of the semiconductor device 100.

The semiconductor device 402 includes ILD layers 408a and 408b, and an ESL 410. Similar to the ILD layers 114, the ILD layers 408a and 408b may each include a low-k oxide material such as silicon oxide (SiOₓ) or undoped silicate glass (USG). Additionally and/or alternatively, the ILD layers 408a and 408b may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 408a and/or 408b includes an ELK dielectric material having a dielectric constant that is less than approximately 2.5. Examples of ELK dielectric materials include carbon doped silicon oxide (C—SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

Similar to the ESLs 116, the ESL 410 may include a silicon nitride (SiₓN_{y}), silicon carbide (SiC), silicon oxynitride (SiON), and/or another suitable dielectric material. In some implementations, an ILD layer 408a and/or 408b and an ESL 410 include different dielectric materials to provide etch selectivity to enable various structures to be formed in an interconnect layer. For example, the ILD layers 408a and 408b may each include a low-k dielectric material such as USG, and the ESL 410 may include a high-k dielectric material such as silicon nitride (SiₓN_{y}) or silicon carbide (SiC), such that a dielectric constant of the ESL 410 is greater than a dielectric constant of one or more of the ILD layers 408a and/or 408b.

Similar to the formation of the bottom interconnect structures 144 in the semiconductor device 100, a masking layer may be formed on the ILD layer 408b in an interconnect layer of the semiconductor device 402. For example, a dielectric masking layer 412 may be formed on the ILD layer 408b. The dielectric masking layer 412 may include a silicon oxynitride material (SiON) and/or another suitable dielectric material.

A deposition tool may be used to deposit the dielectric masking layer 412 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 412 after the dielectric masking layer 412 is deposited.

A photoresist layer may be formed above the dielectric masking layer 412, and a pattern may be formed in the photoresist layer. A deposition tool may be used to form the photoresist layer on the dielectric masking layer 412 (e.g., using a spin-coating technique or another suitable deposition technique). In some implementations, a BARC is first deposited on the dielectric masking layer 412, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 412 based on the pattern in the photoresist layer, to transfer the pattern to the dielectric masking layer 412. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 412 compared to the material of the underlying ILD layer 408b. Thus, the etch operation may stop on the ILD layer 408b with minimal etching to the ILD layer 408b.

As shown in FIG. 4A, another etch operation is performed to etch through the ILD layers 408a, 408b, and through the ESL 410 to form recesses 414 in the memory region 404, and a recess 416 for an alignment mark in the alignment mark region 406. The etch operation may include, for example, a gas-based etch operation in which a different type of etchant is used, as compared to the etchant that was used to transfer the pattern to the dielectric masking layer 412. Thus, the semiconductor device 402 may be transferred from a first etch tool (in which the pattern was transferred to the dielectric masking layer 412) to a second etch tool (in which the ILD layers 408a, 408b, and the ESL 410 are etched) using a wafer/die transport tool to reduce the likelihood of cross-contamination between the first and second etch tools. Alternatively, an etch tool that has multiple processing chambers (e.g., a cluster tool) may be used, and the semiconductor device 402 may be transferred between processing chambers of the etch tool for etching using different types of etchants.

The gas-based etchant that is used to etch the ILD layers 408b, 408a, and the ESL 410, may include a fluorine-based gas etchant that has a higher etch rate for the dielectric materials of the ILD layers 408b, 408a, and the ESL 410, compared to the etch rate of the dielectric masking layer 412. This enables the ILD layers 408b, 408a, and the ESL 410 to be etched with minimal etching to the dielectric masking layer 412. The fluorine-based etchant may include a carbon fluoride-based (CFₓ) gas etchant such as a carbon tetrafluoride (CF₄) gas etchant. Similar to recesses 304 for the bottom interconnect structures 144, the recesses 414 may expose top surfaces of metallization structures (not shown).

Forming the recesses 414 may include etching first portions of the ILD layer 408a and the ILD layer 408b, and forming the recess 416 may include etching second portions of the ILD layer 408a and the ILD layer 408b. The etchings of the first and second portions of the ILD layer 408a and the ILD layer 408b may be performed simultaneously (e.g., in the same etch operation).

As noted herein, a vertical dimension (e.g., height or depth) of bottom electrode vias for memory devices is increased in comparison to vertical dimensions of bottom electrode vias of other memory devices. As a result of the increased vertical dimension, the same etching operation may be used to form the recesses 414 for bottom interconnect structures and to form alignment mark recesses (e.g., recess 416) having a sufficient depth. The vertical dimension D4 (e.g., depth) of the recesses 414 (and for recesses 304) provides for a desired vertical dimension D5 (e.g., depth) of a recess 416 for an alignment mark without having to perform additional etching and use additional etch masks to form a remainder of the recess 416. In some implementations, the vertical (z-direction) dimension D4 is equal to the vertical (z-direction) dimension D5.

Similar to the recesses 304 for the bottom interconnect structures 144, in some implementations, an aspect ratio of each of the recesses 414 is greater than or equal to approximately 5. If the aspect ratio of each of the recesses 414 is smaller than 5, then the geometry of the recesses 414 will not provide sufficient topography for an adjacent alignment mark region 406, so that additional etching and another mask will be needed to form a remainder of a recess 416 in an alignment mark region 406. In addition, an aspect ratio of each of the recesses 414 that is smaller than 5 may result in wider bottom interconnect structures (e.g., greater x-direction dimension), which consumes more chip area. However, other aspect ratio values and ranges are within the scope of this disclosure.

In some implementations, the vertical dimension D4 and the vertical dimension D5 each may be included in the range of approximately 1100 angstroms to approximately 1400 angstroms. As a result of the vertical dimensions D4 and D5 in the range, the same etching operation may be used to form the recesses 414 for bottom interconnect structures and to form recesses 416 having a sufficient depth for alignment marks. The depth (e.g., dimension D4) of the recesses 414 provides for a desired depth (e.g., dimension D5) of a recess 416 for an alignment mark without having to perform additional etching and use additional etch masks to form a remainder of an alignment mark recess. If the vertical dimension D4 of each of the recesses 414 is smaller than 1100 angstroms, then the vertical dimension D4 of the recesses 414 will not provide sufficient topography for an adjacent alignment mark region 406, so that additional etching and another mask will be needed to form a remainder of a recess 416 in an alignment mark region to a required depth. If the vertical dimension D4 is greater than 1400 angstroms, taller/deeper bottom interconnect structures (e.g., greater z-direction dimension) may consume more chip area. In addition, bottom interconnect structures which are too tall/deep may have electrical conductivity issues and/or exhibit increased resistance. However, other values and ranges are within the scope of this disclosure.

As shown in FIG. 4B, conductive material similar to the fill layers 146 may be deposited in the recesses 414 to form bottom interconnect structures 418. In some implementations, a deposition tool is used to deposit the conductive material using a PVD technique, a CVD technique, an ALD technique, and/or another suitable deposition technique to form the bottom interconnect structures 418. The conductive material may include tungsten (W), cobalt (Co), ruthenium (Ru), titanium (Ti), aluminum (Al), copper (Cu), gold (Au), and/or a combination thereof, among other examples of electrically conductive materials. In some implementations, the bottom interconnect structures 418 may include liner layers in the recesses 414 on side and bottom surfaces of the bottom interconnect structures 418. The liner layers may include barrier liners, adhesion liners, and/or another type of liners. Examples of materials for the liner layers include tantalum nitride (TaN) and/or titanium nitride (TiN), among other examples.

An alignment mark 420 is formed in the recess 416. A substrate and/or chip may include one or more alignment marks to facilitate precise and repeatable alignment of the substrate and/or chip across a plurality of semiconductor processing operations. An alignment mark includes a region of the substrate and/or chip that includes an alignment pattern that can be scanned and tracked to fine-tune the orientation of the substrate and/or chip. A laser illumination system of a lithography tool, for example, may scan the pattern of the alignment mark to generate alignment data that may be used to determine whether the alignment of the substrate and/or chip is a pass or a fail.

As shown in FIG. 4B, a vertical dimension D6 in the z-direction (e.g., height or depth) of the bottom interconnect structures 418 is equal to a vertical dimension D7 in the z-direction (e.g., height or depth) of the alignment mark 420. Similar to the vertical dimension D1 of the bottom interconnect structures 144, the vertical dimension D6 of the bottom interconnect structures 418 and the vertical dimension D7 of the alignment mark may be included in the range of approximately 1100 angstroms to 1400 angstroms. If the vertical dimension D6 of each of the bottom interconnect structures 418 is smaller than 1100 angstroms, then the vertical dimension D6 of the bottom interconnect structures 418 will not provide sufficient topography for an alignment mark 420 to be formed in a recess (e.g., recess 416) that was formed in a single etch operation. If the vertical dimension D6 is greater than 1400 angstroms, taller/deeper bottom interconnect structures 418 (e.g., greater z-direction dimension) may consume more chip area. In addition, bottom interconnect structures 418 which are too tall/deep may have electrical conductivity issues and/or exhibit increased resistance. However, other values and ranges are within the scope of this disclosure.

As indicated above, FIGS. 4A and 4B are provided as an example. Other examples may differ from what is described with regard to FIGS. 4A and 4B.

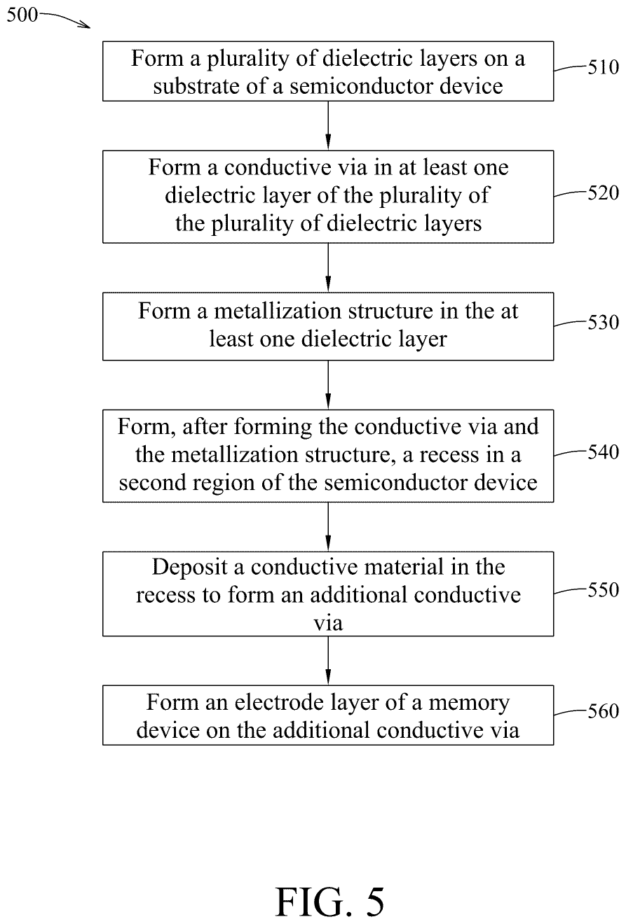

FIG. 5 is a flowchart of an example process 500 associated with a method of forming a semiconductor device. In some implementations, one or more process blocks of FIG. 5 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 5, process 500 may include forming a plurality of dielectric layers on a substrate of a semiconductor device (block 510). For example, one or more semiconductor processing tools may be used to form a plurality of dielectric layers (e.g., ILD layers 114, ESLs 116) on a substrate (e.g., substrate 106) of a semiconductor device (e.g., semiconductor device 100), as described herein. In some implementations, the plurality of dielectric layers are arranged in a first direction (e.g., z-direction).

As further shown in FIG. 5, process 500 may include forming a conductive via in at least one dielectric layer of the plurality of the plurality of dielectric layers (block 520). For example, one or more semiconductor processing tools may be used to form a conductive via (e.g., interconnect structure 124a, 124b) in at least one dielectric layer (e.g., ILD layer 114b) of the plurality of the plurality of dielectric layers, as described herein.

As further shown in FIG. 5, process 500 may include forming a metallization structure in the at least one dielectric layer (block 530). For example, one or more semiconductor processing tools may be used to form a metallization structure (e.g., metallization structure 122f, 122g) in the at least one dielectric layer, as described herein. In some implementations, the metallization structure is over the conductive via in the first direction. In some implementations, the metallization structure and the conductive via are in a first region (e.g., logic region 128) of the semiconductor device.

As further shown in FIG. 5, process 500 may include forming, after forming the conductive via and the metallization structure, a recess in a second region of the semiconductor device (block 540). For example, one or more semiconductor processing tools may be used to form, after forming the conductive via and the metallization structure, a recess (e.g., recess 304) in a second region (e.g., memory region 126) of the semiconductor device, as described herein. In some implementations, the second region is on a lateral side of the first region in a second direction (e.g., x-direction) approximately perpendicular to the first direction. In some implementations, the recess is formed in the at least one dielectric layer and in at least one additional dielectric layer (e.g., ILD layer 114c) over the at least one dielectric layer. In some implementations, a dimension (e.g., vertical dimension D4) of the recess in the first direction is greater than a combined dimension (e.g., combined vertical dimension D2) of the conductive via and the metallization structure in the first direction.

As further shown in FIG. 5, process 500 may include depositing a conductive material in the recess to form an additional conductive via (block 550). For example, one or more semiconductor processing tools may be used to deposit a conductive material (e.g., fill layer 146, liner layer 148) in the recess to form an additional conductive via (e.g., bottom interconnect structure 144), as described herein.

As further shown in FIG. 5, process 500 may include forming an electrode layer of a memory device on the additional conductive via (block 560). For example, one or more semiconductor processing tools may be used to form an electrode layer (e.g., bottom electrode layer 134) of a memory device (e.g., memory device 132a-c) on the additional conductive via, as described herein.

Process 500 may include additional implementations, such as any single implementation or any combination of implementations described below and/or in connection with one or more other processes described elsewhere herein.

In a first implementation, an aspect ratio of the recess is greater than or equal to approximately 5.

In a second implementation, alone or in combination with the first implementation, the dimension of the recess in the first direction is included in a range of approximately 1100 angstroms to approximately 1400 angstroms.

In a third implementation, alone or in combination with one or more of the first and second implementations, process 500 includes forming an alignment mark recess (e.g., recess 416) on a lateral side of the recess (e.g., recess 414) in the second direction, where forming the recess includes etching a first portion of the at least one dielectric layer (e.g., ILD layer 408a) and a first portion of the at least one additional dielectric layer (e.g., ILD layer 408b), where forming the alignment mark recess includes etching a second portion of the at least one dielectric layer and a second portion of the at least one additional dielectric layer, and where etching the first portion of the at least one dielectric layer and the first portion of the at least one additional dielectric layer and etching the second portion of the at least one dielectric layer and the second portion of the at least one additional dielectric layer are performed simultaneously.

In a fourth implementation, alone or in combination with one or more of the first through third implementations, process 500 includes forming an alignment mark recess on a lateral side of the recess in the second direction, where forming the recess includes etching a first portion of the at least one dielectric layer and a first portion of the at least one additional dielectric layer, where forming the alignment mark recess includes etching a second portion of the at least one dielectric layer and a second portion of the at least one additional dielectric layer, and where a dimension of the alignment mark recess (e.g., vertical dimension D5) in the first direction is equal to the dimension (e.g., vertical dimension D4) of the recess in the first direction.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

In this way, a vertical dimension (e.g., height or depth) of bottom electrode vias for a plurality of memory devices is increased in comparison to vertical dimensions of bottom electrode vias of other memory devices. The resulting bottom electrode via vertical dimension provides sufficient topography for an adjacent alignment mark region so that additional etching and an additional mask to form a remainder of an alignment mark region are not needed. In more detail, as a result of the increased vertical dimension, the same etching operation may be used to form recesses for bottom electrode vias and to form alignment mark recesses having a sufficient depth. The depth of the bottom electrode via recesses provides for a desired alignment mark recess depth without having to perform an additional etch operation with another etch mask to form a remainder of an alignment mark recess. In addition, a metallization structure of a metallization layer contacts a top electrode layer located on an MTJ structure of each memory device of the plurality of memory devices. As a result, an intervening common top electrode structure is not required to connect a top metallization layer to the memory devices. Accordingly, masks and etching operations that would be needed to form the top electrode structure can be omitted, and manufacturing processes may be simplified.

As described in greater detail above, some implementations described herein provide a semiconductor device. The semiconductor device includes an interconnect layer including a plurality of inter-layer dielectric (ILD) layers a plurality of etch stop layers (ESLs) interleaving the plurality of ILD layers, a plurality of conductive lines disposed in the plurality of ILD layers, and a plurality of conductive vias, where a first conductive via of the plurality of conductive vias extends in a vertical direction through at least one ESL of the plurality of ESLs between a first conductive line and a second conductive line of the plurality of conductive lines, and where a dielectric constant of the at least one ESL is greater than a dielectric constant of at least one of the plurality of ILD layers. The semiconductor device includes a memory device in the interconnect layer, where the memory device includes a first electrode layer, a magnetic tunnel junction (MTJ) structure on the first electrode layer, and a second electrode layer on the MTJ structure, where the first electrode layer is disposed on a second conductive via of the plurality of conductive vias, and where a dimension of the second conductive via in the vertical direction is greater than a combined dimension of the first conductive via and one of the first conductive line or the second conductive line in the vertical direction.

As described in greater detail above, some implementations described herein provide a method. The method includes forming a plurality of dielectric layers on a substrate of a semiconductor device, where the plurality of dielectric layers are arranged in a first direction. The method includes forming a conductive via in at least one dielectric layer of the plurality of the plurality of dielectric layers. The method includes forming a metallization structure in the at least one dielectric layer, where the metallization structure is over the conductive via in the first direction, and where the metallization structure and the conductive via are in a first region of the semiconductor device. The method includes forming, after forming the conductive via and the metallization structure, a recess in a second region of the semiconductor device, where the second region is on a lateral side of the first region in a second direction approximately perpendicular to the first direction, where the recess is formed in the at least one dielectric layer and in at least one additional dielectric layer over the at least one dielectric layer, and where a dimension of the recess in the first direction is greater than a combined dimension of the conductive via and the metallization structure in the first direction. The method includes depositing a conductive material in the recess to form an additional conductive via. The method includes forming an electrode layer of a memory device on the additional conductive via.

As described in greater detail above, some implementations described herein provide a semiconductor device. The semiconductor device includes a device layer. The semiconductor device includes an interconnect layer disposed over the device layer, where the interconnect layer includes a plurality of dielectric layers, where the plurality of dielectric layers include a plurality of metal lines disposed in the plurality of dielectric layers, where a first metal line in a first dielectric layer of the plurality of dielectric layers is spaced apart from a second metal line in a second dielectric layer of the plurality of dielectric layers, and where the first metal line is electrically coupled to the second metal line by a via. The semiconductor device includes a plurality of memory devices arranged side-by-side in a first direction in the interconnect layer, where each memory device of the plurality of memory devices includes an electrode layer, and a data-storing portion on the electrode layer, where the electrode layer is disposed in a third dielectric layer over the second dielectric layer, and on an electrode via of a plurality of electrode vias, where the electrode via extends in a second direction approximately perpendicular to the first direction between the electrode layer and an underlying metal line of the plurality of metal lines, and where the underlying metal line is in the first dielectric layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an interconnect layer comprising:
a plurality of inter-layer dielectric (ILD) layers;
a plurality of etch stop layers (ESLs) interleaving the plurality of ILD layers;
a plurality of conductive lines disposed in the plurality of ILD layers; and
a plurality of conductive vias,
wherein a first conductive via of the plurality of conductive vias extends in a vertical direction through at least one ESL of the plurality of ESLs between a first conductive line and a second conductive line of the plurality of conductive lines, and
wherein a dielectric constant of the at least one ESL is greater than a dielectric constant of at least one of the plurality of ILD layers;
a memory device in the interconnect layer,
wherein the memory device comprises:
a first electrode layer;
a magnetic tunnel junction (MTJ) structure on the first electrode layer; and
a second electrode layer on the MTJ structure,
wherein the first electrode layer is disposed on a second conductive via of the plurality of conductive vias, and
wherein a dimension of the second conductive via in the vertical direction is greater than a combined dimension of the first conductive via and one of the first conductive line or the second conductive line in the vertical direction.

2. The semiconductor device of claim 1, wherein an aspect ratio of the second conductive via is greater than or equal to approximately 5.

3. The semiconductor device of claim 1, wherein the dimension of the second conductive via in the vertical direction is included in a range of approximately 1100 angstroms to approximately 1400 angstroms.

4. The semiconductor device of claim 1, wherein the second conductive line and the first conductive via are disposed in a first ILD layer of the plurality of ILD layers, and
wherein the second conductive via is disposed in the first ILD layer and in a second ILD layer of the plurality of ILD layers disposed over the first ILD layer.

5. The semiconductor device of claim 4, wherein the second conductive via lands on a third conductive line of the plurality of conductive lines, and
wherein the third conductive line is in a same metallization layer as the first conductive line.

6. The semiconductor device of claim 4, wherein the second conductive via extends in the vertical direction from the second ILD layer through a top surface of the first ILD layer and a bottom surface of the first ILD layer.

7. The semiconductor device of claim 4, further comprising a plurality of spacer layers disposed on sides of the MTJ structure,
wherein the plurality of spacer layers are disposed over the first ILD layer, and
wherein a majority portion of the second conductive via is disposed in the first ILD layer.

8. The semiconductor device of claim 1, further comprising a third conductive line of the plurality of conductive lines,
wherein the third conductive line is in physical contact with the second electrode layer.

9. A method, comprising:
forming a plurality of dielectric layers on a substrate of a semiconductor device,
wherein the plurality of dielectric layers are arranged in a first direction;
forming a conductive via in at least one dielectric layer of the plurality of the plurality of dielectric layers;
forming a metallization structure in the at least one dielectric layer,
wherein the metallization structure is over the conductive via in the first direction, and
wherein the metallization structure and the conductive via are in a first region of the semiconductor device;
forming, after forming the conductive via and the metallization structure, a recess in a second region of the semiconductor device,
wherein the second region is on a lateral side of the first region in a second direction approximately perpendicular to the first direction,
wherein the recess is formed in the at least one dielectric layer and in at least one additional dielectric layer over the at least one dielectric layer, and
wherein a dimension of the recess in the first direction is greater than a combined dimension of the conductive via and the metallization structure in the first direction;
depositing a conductive material in the recess to form an additional conductive via; and
forming an electrode layer of a memory device on the additional conductive via.

10. The method of claim 9, wherein an aspect ratio of the recess is greater than or equal to approximately 5.

11. The method of claim 9, wherein the dimension of the recess in the first direction is included in a range of approximately 1100 angstroms to approximately 1400 angstroms.

12. The method of claim 9, further comprising forming an alignment mark recess on a lateral side of the recess in the second direction,
wherein forming the recess comprises etching a first portion of the at least one dielectric layer and a first portion of the at least one additional dielectric layer,
wherein forming the alignment mark recess comprises etching a second portion of the at least one dielectric layer and a second portion of the at least one additional dielectric layer, and
wherein etching the first portion of the at least one dielectric layer and the first portion of the at least one additional dielectric layer and etching the second portion of the at least one dielectric layer and the second portion of the at least one additional dielectric layer are performed simultaneously.

13. The method of claim 9, further comprising forming an alignment mark recess on a lateral side of the recess in the second direction,
wherein forming the recess comprises etching a first portion of the at least one dielectric layer and a first portion of the at least one additional dielectric layer,
wherein forming the alignment mark recess comprises etching a second portion of the at least one dielectric layer and a second portion of the at least one additional dielectric layer, and
wherein a dimension of the alignment mark recess in the first direction is equal to the dimension of the recess in the first direction.

14. A semiconductor device, comprising:
a device layer;
an interconnect layer disposed over the device layer,
wherein the interconnect layer comprises a plurality of dielectric layers,
wherein the plurality of dielectric layers comprise a plurality of metal lines disposed in the plurality of dielectric layers,
wherein a first metal line in a first dielectric layer of the plurality of dielectric layers is spaced apart from a second metal line in a second dielectric layer of the plurality of dielectric layers, and
wherein the first metal line is electrically coupled to the second metal line by a via;
a plurality of memory devices arranged side-by-side in a first direction in the interconnect layer,
wherein each memory device of the plurality of memory devices comprises:
an electrode layer; and
a data-storing portion on the electrode layer,
wherein the electrode layer is disposed in a third dielectric layer over the second dielectric layer, and on an electrode via of a plurality of electrode vias,
wherein the electrode via extends in a second direction approximately perpendicular to the first direction between the electrode layer and an underlying metal line of the plurality of metal lines, and
wherein the underlying metal line is in the first dielectric layer.

15. The semiconductor device of claim 14, wherein the electrode via lands on a top surface of the underlying metal line, and
wherein the top surface of the underlying metal line is approximately co-planar with a top surface of the first metal line.

16. The semiconductor device of claim 14, wherein a height of the electrode via in the second direction exceeds a total height in the second direction of the second metal line and of the via.

17. The semiconductor device of claim 14, wherein the first metal line, the second metal line, and the via are in a first region of the semiconductor device,
wherein the plurality of memory devices is in a second region of the semiconductor device, and
wherein the second region is on a side of the first region in the first direction.

18. The semiconductor device of claim 14, wherein each memory device of the plurality of memory devices further comprises an additional electrode layer on the data-storing portion, and
wherein the interconnect layer further comprises an additional metal line commonly connected to the additional electrode layer of each memory device.

19. The semiconductor device of claim 18, wherein the additional metal line contacts a surface of the additional electrode layer of each memory device.

20. The semiconductor device of claim 19, wherein the surface of the additional electrode layer of each memory device is curved.
